(19) United States
(12) Patent Application Publication
(10) Pub. No.: US 2025/0194284 A1
(43) Pub. Date: Jun. 12, 2025

(54) SOLID-STATE IMAGING DEVICE AND ELECTRONIC APPARATUS

(71) Applicant: SONY SEMICONDUCTOR SOLUTIONS CORPORATION, KANAGAWA (JP)

(72) Inventors: MASAHIKO YUKAWA, KANAGAWA (JP); NAOKI OGAWA, KANAGAWA (JP); SUGURU SAITO, KANAGAWA (JP); NOBUTOSHI FUJII, KANAGAWA (JP); AKIHISA SAKAMOTO, KANAGAWA (JP)

(21) Appl. No.: 18/729,561

(22) PCT Filed: Dec. 28, 2022
(86) PCT No.: PCT/JP2022/048693

§ 371 Date: Feb. 17, 2025

(30) Foreign Application Priority Data
Jan. 25, 2022 (JP) 2022-009715

(51) Int. Cl. H10F 39/00; H10F 39/18; H10F 77/12; H10F 77/14; H10F 77/60

(52) U.S. Cl. CPC H10F 39/811; H10F 39/014; H10F 39/18; H10F 39/804; H10F 77/12; H10F 77/147; H10F 77/60

(57) ABSTRACT

A solid-state imaging device and an electronic apparatus are to be provided to solve problems in processing in a structure in which an active chip is bonded to the wafer of a solid-state imaging element chip and is covered with an insulating film such as an oxide film.

The solid-state imaging device includes: a solid-state imaging element chip; an active chip bonded to the lower surface of the solid-state imaging element chip; a dummy chip that is bonded to the lower surface of an electrode pad of the solid-state imaging element chip and has an end surface parallel to the cutting plane of the solid-state imaging element chip cut out from a wafer; and a planarized insulating film that covers the bonding surface, or a solid-state imaging element chip; an active chip bonded to the solid-state imaging element chip; one or more dummy chips that are bonded to a free region on the bonding surface; and a planarized insulating film that covers the bonding surface side, or a solid-state imaging element chip; an active chip bonded to the solid-state imaging element chip; a planarized insulating film that covers the peripheral side surfaces and the lower surface of the active chip; and a silicon substrate that surrounds the peripheral side surfaces of the insulating film and has a lower surface formed in the same plane as the insulating film.

### TECHNICAL FIELD

The present disclosure relates to a solid-state imaging device and an electronic apparatus including the solid-state imaging device.

### BACKGROUND ART

Conventionally, a higher degree of integration and a higher level of performance of semiconductor elements have been achieved by miniaturization of transistors and wiring lines. However, as miniaturization progresses, an increase in development and manufacturing costs becomes a problem. Therefore, in recent years, dies and packages for integrated circuits having different functions are manufactured by optimal processes and are three-dimensionally stacked, to achieve higher integration and higher performance of semiconductor elements.

To lower the costs of solid-state imaging devices and the like, CoW (Chip on Wafer) for directly bonding a chip onto a wafer, and CoC (Chip on Chip) for directly bonding a chip onto a chip have been developed as bonding techniques that enable mixed mounting of chips of a plurality of kinds of logic circuits, chips of memory circuits, and the like, for example.

Specifically, by CoW, for example, a non-defective chip (a known good die (KGD)) manufactured and inspected in a different process is copper-copper (Cu—Cu) connected (hereinafter referred to as “Cu—Cu connection”) to a solid-state imaging element chip that has been inspected and determined to be a non-defective chip on a wafer, so that the chips are stacked.

Cu—Cu connection is to connect a solid-state imaging element chip and a chip of a memory circuit or a chip of a logic circuit directly to each other at terminals formed with copper (Cu) in the respective lamination planes, for example. This eliminates the need to cause a through electrode (a through silicon via, hereinafter referred to as “TSV”) or the like to penetrate a solid-state imaging element chip, and makes the occupied area for connection unnecessary. Thus, it is possible to reduce the size and improve the productivity of solid-state imaging devices.

Further, in a CoW structure and a CoC structure, the entire bonded logic chip and memory chip are covered with an insulating film such as an oxide film, so that insulation properties are secured, and each chip is protected.

However, with the recent evolution of the semiconductor manufacturing technology, logic chips, memory chips, and the like have been becoming smaller in size more rapidly than solid-state imaging element chips. For this reason, even if a plurality of logic chips, a memory chip, and the like are bonded to the back surface of a solid-state imaging element chip, the back surface of the solid-state imaging element chip still has regions not bonded to the regions to which the chips are bonded.

When such a surface is covered with an oxide film, steps appear even if the oxide film is buried between the logic chips and the memory chip. Further, planarization with the steps remaining might result in insufficient planarization. Therefore, when the planarized surface is bonded to a support substrate as it is, there is a possibility that voids will appear in the bonded surfaces, and a bonding failure will occur.

Furthermore, since the logic chips and the memory chip are not bonded to the scribed line for singulation, the oxide film in the scribed line regions is thick. Since an oxide film such as a silicon dioxide film is a hard material, quality degradation such as cracks and chipping occurs when a processed portion is finished into a rectangular shape in the dicing process with a blade.

Further, the lower surface of an electrode pad is a laminate of a thin silicon (Si:hereinafter referred to as “silicon” unless otherwise specified)-based substrate of the solid-state imaging element chip and an oxide film. Therefore, the lower surface is a structure in which cracks are likely to appear due to the impact of wire bonding when the electrode is connected at the time of mounting.

Furthermore, distortion appears due to a difference in linear expansion coefficient between the oxide film and the logic chip or the like, and the distortion is transferred to the solid-state imaging element chip side. As a result, deviation of the on-chip lens occurs, and the characteristics of the transistors constituting the circuit fluctuate.

As described above, because of the problems such as the above that occur when logic chips and memory chips are three-dimensionally integrated, it is required to improve the yield in manufacturing, secure product characteristics, and increase reliability.

Patent Document 1 is disclosed as a conventional technique related to such a Cow technology and a CoC technology for bonding non-defective logic chips and memory chips to a non-defective chip on a wafer.

Patent Document 1 discloses a back-illuminated solid-state imaging device including: a first semiconductor element including an imaging element that generates a pixel signal on a pixel basis; a second semiconductor element in which a signal processing circuit necessary for signal processing of the pixel signal is covered (buried) with a coating film (embedding member); and a wiring line that electrically connects the first semiconductor element and the second semiconductor element, in which the first semiconductor element and the second semiconductor element are stacked by oxide film bonding.

Specifically, a singulated memory chip and a logic chip are disposed on a solid-state imaging element chip on a wafer, and are Cu—Cu connected. Next, the memory chip and the logic chip are made thinner, the memory chip and the logic chip are covered with an oxide film, and the oxide film is planarized. Next, the resultant is bonded to a support substrate, the wafer of the solid-state imaging element chip is made thinner, and a color filter or a microlens array is mounted on the surface on the light receiving side of the wafer of the solid-state imaging element chip. Thus, a solid-state imaging element chip can be formed.

### CITATION LIST

### Patent Document

Patent Document 1: WO 2019/087764 A

### SUMMARY OF THE INVENTION

### Problems to be Solved by the Invention

However, by the technique disclosed in Patent Document 1, an oxide film is formed to cover the logic chip and the memory chip. Therefore, there are no disclosures of a solution to the processing problem that occurs when logic chips and memory chips are three-dimensionally integrated as above, and a specific solution to problems such as the stress to be generated by bonding and coating with the oxide film.

Meanwhile, there are disclosures about enhancement of heat dissipation efficiency by mounting dummy chips and laying out dummy chips so as to narrow gaps. However, there are no disclosures about the specific shape, the layout, and the like of the dummy chips, and a specific countermeasure for the problem to be caused by the difference in the linear expansion coefficient of the buried insulating material.

The present disclosure has been made in view of such problems, and an object thereof is to provide a solid-state imaging device that solves some of the processing problems in a structure in which active chips are bonded to the wafer of a solid-state imaging element chip, and the active chips are covered with an insulating film such as an oxide film, and an electronic apparatus including the solid-state imaging device.

### Solutions to Problems

The present disclosure is made to solve the above problems, and a first aspect thereof is a solid-state imaging device that includes: a solid-state imaging element chip; at least one active chip that is bonded to the lower surface of the solid-state imaging element chip; a dummy chip that is bonded to the lower surface of an electrode pad of the solid-state imaging element chip, and has an end surface parallel to the cutting plane of the solid-state imaging element chip cut out from a wafer; and a planarized insulating film that covers the bonding surface of the solid-state imaging element chip including the active chip and the dummy chip.

Also, in the first aspect, the active chip may be a logic chip, a memory chip, or a processor chip.

Further, in the first aspect, the electrode pad may be disposed at both ends or peripheral ends of the upper surface of the solid-state imaging element chip, and the dummy chip may be bonded in such a manner as to have an end surface in the same plane as the cutting plane of the solid-state imaging element chip.

Also, in the first aspect, the electrode pad may be disposed at both ends or peripheral ends of the upper surface of the solid-state imaging element chip, and the active chip or the dummy chip may be bonded in such a manner as to have a planar end surface adjacent to the cutting plane of the solid-state imaging element chip.

Further, in the first aspect, the solid-state imaging element chip may be Cu—Cu connected to the active chip or the dummy chip.

Also, in the first aspect, the solid-state imaging element chip may be Cu—Cu connected to the active chip, and be bonded to the dummy chip with an insulating film.

Further, in the first aspect, the solid-state imaging element chip may have a laminated structure including a photodiode formation layer and a photodiode wiring layer in which the electrode pad is disposed, and be Cu—Cu connected to the active chip or the dummy chip.

Also, in the first aspect, the solid-state imaging element chip may have a laminated structure including a photodiode formation layer and a photodiode wiring layer in which the electrode pad is disposed, be Cu—Cu connected to the active chip, and be bonded to the dummy chip with an insulating film.

A second aspect of the present disclosure is a solid-state imaging device that includes:
a solid-state imaging element chip;
at least one active chip that is bonded to the solid-state imaging element chip;
at least one dummy chip that is bonded to a free region on the bonding surface of the active chip of the solid-state imaging element chip, the active chip not being bonded to the free region; and
a planarized insulating film that covers the bonding surface side of the solid-state imaging element chip including the active chip and the dummy chip.

Also, in the second aspect, a plurality of rectangular or strip-shaped dummy chips smaller than the active chip may be bonded to the free region to which the active chip is not bonded.

Further, in the second aspect, the dummy chip may be formed in a square or strip-like shape having the minimum short side of the free region as one side at a distance of at least 0.5 μm from an end surface of the active chip bonded to the solid-state imaging element chip, and the dummy chip may be bonded to the free region, with the distance being secured.

Also, in the second aspect, the dummy chip may contain at least one of silicon (Si), aluminum oxide (Al₂O₃), silicon carbide (Sic), aluminum nitride (AlN), silicon nitride (Si₃N₄), titanium (Ti), titanium nitride (TiN), carbon (C), silicon carbonitride (SiCN), polysilicon, or tantalum nitride (TaN).

Further, in the second aspect, in the dummy chip or the active chip, at least one of silicon (Si), aluminum oxide (Al₂O₃), silicon carbide (Sic), aluminum nitride (AlN), silicon nitride (Si₃N₄), titanium (Ti), titanium nitride (TiN), aluminum (Al), carbon (C), silicon carbonitride (SiCN), polysilicon, or tantalum nitride (TaN), which is a material having a polishing rate of 20 or higher with respect to silicon dioxide (SiO₂), may be stacked on the surface on the opposite side from the surface bonded to the solid-state imaging element chip.

Also, in the second aspect, the dummy chip may include a heat transfer member that is formed with a material having a higher thermal conductivity than the thermal conductivity of silicon dioxide (SiO₂), and be stacked on a single layer or multiple layers.

A third aspect of the present disclosure is a solid-state imaging device that includes: a solid-state imaging element chip; at least one active chip that is bonded to the solid-state imaging element chip; a silicon substrate that is bonded to the solid-state imaging element chip in such a manner as to surround the peripheral side surfaces of the active chip; and a planarized insulating film that covers a region between the active chip and the silicon substrate, and at least the lower surface of the active chip.

Also, in the third aspect, a peripheral side surface of the silicon substrate may be formed in the same plane as a peripheral side surface of the solid-state imaging element chip.

Further, in the third aspect, a step continuing from a peripheral side surface of the solid-state imaging element chip to a peripheral side surface of an upper portion of the silicon substrate may be formed.

Also, in the third aspect, a support substrate may be bonded to the lower surface of the silicon substrate or the insulating film.

Further, in the third aspect, a peripheral side surface of the insulating film in contact with the silicon substrate may have a tapered portion that extends from the bonding surface of the solid-state imaging element chip and be wider at a lower portion.

Also, in the third aspect, the insulating film may be formed with an insulating resin.

A fourth aspect of the present disclosure is a method for manufacturing a solid-state imaging device, the method including: a step of bonding an active chip to the lower surface of a solid-state imaging element chip on a wafer; a step of bonding a silicon substrate to the lower surface of the solid-state imaging element chip, a dug portion or a hollow portion being formed in the silicon substrate, the dug portion or the hollow portion having a shape that avoids contact with the active chip; a step of thinning the lower surface of the silicon substrate to leave part of the silicon substrate between the active chips; a step of stacking an insulating film on the lower surface of the solid-state imaging element chip to cover a region between the active chip and the remaining silicon substrate; and a step of planarizing the covering insulating film.

A fifth aspect of the present disclosure is an electronic apparatus that includes

a solid-state imaging device including: a solid-state imaging element chip; at least one active chip that is bonded to the lower surface of the solid-state imaging element chip; a dummy chip that is bonded to the lower surface of an electrode pad of the solid-state imaging element chip and has an end surface parallel to the cutting plane of the solid-state imaging element chip cut out from a wafer; and a planarized insulating film that covers the bonding surface of the solid-state imaging element chip including the active chip and the dummy chip,

a solid-state imaging device including: a solid-state imaging element chip; at least one active chip that is bonded to the solid-state imaging element chip; at least one dummy chip that is bonded to a free region on the bonding surface of the active chip of the solid-state imaging element chip, the active chip not being bonded to the free region; and a planarized insulating film that covers the bonding surface side of the solid-state imaging element chip including the active chip and the dummy chip, or

a solid-state imaging device including: a solid-state imaging element chip; at least one active chip that is bonded to the solid-state imaging element chip; a silicon substrate that is bonded to the solid-state imaging element chip in such a manner as to surround a peripheral side surface of the active chip; and a planarized insulating film that covers a region between the active chip and the silicon substrate, and at least the lower surface of the active chip.

By adopting the above aspects, it is possible to provide a solid-state imaging device, a method for manufacturing a solid-state imaging device, and an electronic apparatus that solve the problems in processing in a structure in which chips are bonded to the wafer of solid-state imaging elements, and the chips are covered with an insulating film such as an oxide film.

### BRIEF DESCRIPTION OF DRAWINGS

FIG. 1 is an explanatory diagram of the CoW structure of a solid-state imaging element chip according to the present disclosure.

FIG. 2 is a diagram illustrating a state in which a logic chip or the like is bonded to a solid-state imaging element chip formed on a wafer.

FIG. 3 is a plan view illustrating a schematic structure of a basic form of a first embodiment of a solid-state imaging device according to the present disclosure.

FIG. 4 is an X1-X1 cross-sectional end view illustrating a schematic structure of the basic form of the first embodiment of a solid-state imaging device according to the present disclosure.

FIG. 5 is a plan view illustrating a schematic configuration of a first modification of the first embodiment of a solid-state imaging device according to the present disclosure.

FIG. 6 is a plan view illustrating a schematic configuration of a second modification of the first embodiment of a solid-state imaging device according to the present disclosure.

FIG. 7 is an X2-X2 cross-sectional end view illustrating a schematic structure of a third modification of the first embodiment of a solid-state imaging device according to the present disclosure.

FIG. 8 is an X2-X2 cross-sectional end view illustrating a schematic structure of a fourth modification of the first embodiment of a solid-state imaging device according to the present disclosure.

FIG. 9 is an X2-X2 cross-sectional end view illustrating a schematic structure of a fifth modification of the first embodiment of a solid-state imaging device according to the present disclosure.

FIG. 10 is an X2-X2 cross-sectional end view illustrating a schematic structure of a sixth modification of the first embodiment of a solid-state imaging device according to the present disclosure.

FIG. 11 is a diagram for explaining a method for manufacturing the first embodiment of a solid-state imaging device according to the present disclosure.

FIG. 12 is a Y1-Y1 cross-sectional end view illustrating a first example of a schematic structure of a basic form of a second embodiment of a solid-state imaging device according to the present disclosure, and a bottom view of the first example.

FIG. 13 is a Y1-Y1 cross-sectional end view illustrating a second example of a schematic structure of the basic form of the second embodiment of a solid-state imaging device according to the present disclosure, and a bottom view of the second example.

FIG. 14 is a partially enlarged view of a Y1-Y1 cross-sectional end view illustrating a comparative example in a case where any dummy chip is not bonded in the example illustrated in FIG. 12.

FIG. 15 is an explanatory view in which tensile stress can be reduced by bonding a dummy chip in the basic form of the second embodiment of a solid-state imaging device according to the present disclosure.

FIG. 16 is an explanatory diagram illustrating a comparative example of planarization in a case where any dummy chip is not bonded to a solid-state imaging element chip (part 1).

FIG. 17 is an explanatory diagram illustrating a comparative example of planarization in a case where any dummy chip is not bonded to a solid-state imaging element chip (part 2).

FIG. 18 is an explanatory diagram illustrating a comparative example of planarization in a case where any dummy chip is not bonded to a solid-state imaging element chip (part 3).

FIG. 19 is a diagram for explaining the effects of planarization by bonding dummy chips in the basic form of the second embodiment of a solid-state imaging device according to the present disclosure (part 1).

FIG. 20 is a diagram for explaining the effects of planarization by bonding dummy chips in the basic form of the second embodiment of a solid-state imaging device according to the present disclosure (part 2).

FIG. 21 is a diagram for explaining the effects of planarization by bonding dummy chips in the basic form of the second embodiment of a solid-state imaging device according to the present disclosure (part 3).

FIG. 22 is a bottom view illustrating a first example of a schematic structure of a first modification of the second embodiment of a solid-state imaging device according to the present disclosure.

FIG. 23 is a bottom view illustrating a second example of a schematic structure of the first modification of the second embodiment of a solid-state imaging device according to the present disclosure.

FIG. 24 is a bottom view illustrating a third example of a schematic structure of the first modification of the second embodiment of a solid-state imaging device according to the present disclosure.

FIG. 25 is a bottom view illustrating a first example of a schematic structure of a second modification of the second embodiment of a solid-state imaging device according to the present disclosure.

FIG. 26 is a bottom view illustrating a second example of a schematic structure of the second modification of the second embodiment of a solid-state imaging device according to the present disclosure.

FIG. 27 is a bottom view illustrating a third example of a schematic structure of the second modification of the second embodiment of a solid-state imaging device according to the present disclosure.

FIG. 28 is a bottom view illustrating a first example of a schematic structure of a third modification of the second embodiment of a solid-state imaging device according to the present disclosure.

FIG. 29 is a bottom view illustrating a second example of a schematic structure of the third modification of the second embodiment of a solid-state imaging device according to the present disclosure.

FIG. 30 is a bottom view illustrating a third example of a schematic structure of the third modification of the second embodiment of a solid-state imaging device according to the present disclosure.

FIG. 31 is a bottom view of the wafer of solid-state imaging element chips illustrating an example of a schematic structure of a fourth modification of the second embodiment of a solid-state imaging device according to the present disclosure, and is a view illustrating a singulated state.

FIG. 32 is a Y1-Y1 cross-sectional end view illustrating a schematic structure of a fifth modification of the second embodiment of a solid-state imaging device according to the present disclosure, to which a dummy chip and the like are bonded.

FIG. 33 is a Y1-Y1 cross-sectional end view illustrating a schematic structure of a sixth modification of the second embodiment of a solid-state imaging device according to the present disclosure, to which a dummy chip and the like are bonded.

FIG. 34 is a plan view illustrating a schematic structure of a basic form of a third embodiment of a solid-state imaging device according to the present disclosure.

FIG. 35 is an X1-X1 cross-sectional end view illustrating a schematic structure of the basic form of the third embodiment of a solid-state imaging device according to the present disclosure.

FIG. 36 is a schematic end view illustrating a schematic structure of the basic form of the third embodiment of a solid-state imaging device according to the present disclosure.

FIG. 37 is a schematic end view illustrating a schematic structure of a first modification of the third embodiment of a solid-state imaging device according to the present disclosure.

FIG. 38 is a schematic end view illustrating a schematic structure of a second modification of the third embodiment of a solid-state imaging device according to the present disclosure.

FIG. 39 is a schematic end view illustrating a schematic structure of a third modification of the third embodiment of a solid-state imaging device according to the present disclosure.

FIG. 40 is a schematic end view illustrating a schematic structure of a fourth modification of the third embodiment of a solid-state imaging device according to the present disclosure.

FIG. 41 is a schematic end view illustrating a schematic structure of an eighth modification of the third embodiment of a solid-state imaging device according to the present disclosure.

FIG. 42 is a schematic end view illustrating a schematic structure of a sixteenth modification of the third embodiment of a solid-state imaging device according to the present disclosure.

FIG. 43 is a schematic end view illustrating a schematic structure of a seventeenth modification of the third embodiment of a solid-state imaging device according to the present disclosure.

FIG. 44 is a diagram for explaining a case where the planar shape of a dug portion or a hollow portion of a silicon substrate of a solid-state imaging device according to the present disclosure is a square shape.

FIG. 45 is a diagram for explaining a case where the planar shape of a dug portion or a hollow portion of a silicon substrate of a solid-state imaging device according to the present disclosure is a rectangular shape.

FIG. 46 is a diagram for explaining a case where the planar shape of a dug portion or a hollow portion of a silicon substrate of a solid-state imaging device according to the present disclosure is a shape obtained by joining two large and small rectangles.

FIG. 47 is a diagram for explaining a case where the planar shape of a dug portion or a hollow portion of a silicon substrate of a solid-state imaging device according to the present disclosure is a shape obtained by joining the base of a trapezoid to a side of a rectangle.

FIG. 48 is a diagram for explaining a basic form of a method for manufacturing the third embodiment of a solid-state imaging device according to the present disclosure (part 1).

FIG. 49 is a diagram for explaining the basic form of the method for manufacturing the third embodiment of a solid-state imaging device according to the present disclosure (part 2).

FIG. 50 is a diagram for explaining the basic form of the method for manufacturing the third embodiment of a solid-state imaging device according to the present disclosure (part 3).

FIG. 51 is a diagram for explaining the basic form of the method for manufacturing the third embodiment of a solid-state imaging device according to the present disclosure (part 4).

FIG. 52 is a diagram for explaining the basic form of the method for manufacturing the third embodiment of a solid-state imaging device according to the present disclosure (part 5).

FIG. 53 is a diagram for explaining the basic form of the method for manufacturing the third embodiment of a solid-state imaging device according to the present disclosure (part 6).

FIG. 54 is a diagram for explaining the basic form of the method for manufacturing the third embodiment of a solid-state imaging device according to the present disclosure (part 7).

FIG. 55 is a diagram for explaining the basic form of the method for manufacturing the third embodiment of a solid-state imaging device according to the present disclosure (part 8).

FIG. 56 is a diagram for explaining the basic form of the method for manufacturing the third embodiment of a solid-state imaging device according to the present disclosure (part 9).

FIG. 57 is a diagram for explaining the basic form of the method for manufacturing the third embodiment of a solid-state imaging device according to the present disclosure (part 10).

FIG. 58 is a diagram for explaining the basic form of the method for manufacturing the third embodiment of a solid-state imaging device according to the present disclosure (part 11).

FIG. 59 is a diagram for explaining a first modification of the method for manufacturing the third embodiment of a solid-state imaging device according to the present disclosure (part 1).

FIG. 60 is a diagram for explaining the first modification of the method for manufacturing the third embodiment of a solid-state imaging device according to the present disclosure (part 2).

FIG. 61 is a diagram for explaining the first modification of the method for manufacturing the third embodiment of a solid-state imaging device according to the present disclosure (part 3).

FIG. 62 is a diagram for explaining a second modification of the method for manufacturing the third embodiment of a solid-state imaging device according to the present disclosure (part 1).

FIG. 63 is a diagram for explaining the second modification of the method for manufacturing the third embodiment of a solid-state imaging device according to the present disclosure (part 2).

FIG. 64 is a diagram for explaining a third modification of the method for manufacturing the third embodiment of a solid-state imaging device according to the present disclosure (part 1).

FIG. 65 is a diagram for explaining the third modification of the method for manufacturing the third embodiment of a solid-state imaging device according to the present disclosure (part 2).

FIG. 66 is a diagram for explaining the third modification of the method for manufacturing the third embodiment of a solid-state imaging device according to the present disclosure (part 3).

FIG. 67 is a diagram for explaining the third modification of the method for manufacturing the third embodiment of a solid-state imaging device according to the present disclosure (part 4).

FIG. 68 is a diagram for explaining the third modification of the method for manufacturing the third embodiment of a solid-state imaging device according to the present disclosure (part 5).

FIG. 69 is a diagram for explaining the third modification of the method for manufacturing the third embodiment of a solid-state imaging device according to the present disclosure (part 6).

FIG. 70 is a diagram for explaining the third modification of the method for manufacturing the third embodiment of a solid-state imaging device according to the present disclosure (part 7).

FIG. 71 is a diagram for explaining the third modification of the method for manufacturing the third embodiment of a solid-state imaging device according to the present disclosure (part 8).

FIG. 72 is a diagram for explaining a fourth modification of the method for manufacturing the third embodiment of a solid-state imaging device according to the present disclosure (part 1).

FIG. 73 is a diagram for explaining the fourth modification of the method for manufacturing the third embodiment of a solid-state imaging device according to the present disclosure (part 2).

FIG. 74 is a diagram for explaining the fourth modification of the method for manufacturing the third embodiment of a solid-state imaging device according to the present disclosure (part 3).

FIG. 75 is a diagram for explaining the fourth modification of the method for manufacturing the third embodiment of a solid-state imaging device according to the present disclosure (part 4).

FIG. 76 is a block diagram illustrating an example configuration of an electronic apparatus including a solid-state imaging device according to the present disclosure.

### MODE FOR CARRYING OUT THE INVENTION

Next, modes for carrying out the present disclosure (these modes will be hereinafter referred to as “embodiments”) are described in the following order with reference to the drawings. In the drawings described below, the same or similar parts are denoted by the same or similar reference signs. However, the drawings are schematic, and dimensional ratios and the like of the respective parts do not necessarily match actual ones. Furthermore, it goes without saying that dimensional relationships and ratios are partly different between the drawings.
1. First embodiment of a solid-state imaging device according to the present disclosure
2. Method for manufacturing the first embodiment of a solid-state imaging device according to the present disclosure
3. Second embodiment of a solid-state imaging device according to the present disclosure
4. Method for manufacturing the second embodiment of a solid-state imaging device according to the present disclosure
5. Third embodiment of a solid-state imaging device according to the present disclosure
6. Method for manufacturing the third embodiment of a solid-state imaging device according to the present disclosure
7. Example configuration of an electronic apparatus

### 1. First Embodiment of a Solid-State Imaging Device According to the Present Disclosure

### [Outline of a Cow Structure]

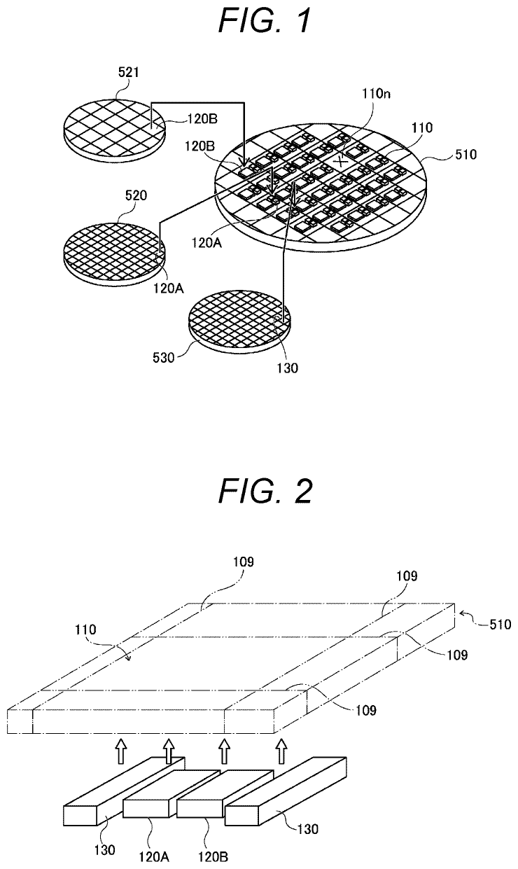

Before a specific description of a solid-state imaging device 100 according to the present disclosure is started, an outline of a CoW structure as a premise of the structure of the solid-state imaging device will be described in the description below, with reference to FIGS. 1 and 2.

Note that, in the description below, “upper” as in an “upper surface”, an “upper side”, or the like, or “lower” as in a “lower surface”, a “lower side”, or the like means that the light receiving surface side of a pixel region 103 of a solid-state imaging element chip 110 is the “upper” side, and the opposite side is the “lower” side. Furthermore, as the solid-state imaging device 100, the semiconductor chip portion of solid-state imaging element chips 110 or the like is packaged, but the package is neither explained nor shown in the following description and drawings.

Also, in the description below, a chip having an electrical function, such as a logic chip 120A, a memory chip 120B, or a processor chip 131 described later, will be collectively referred to as an active chip 120 in some cases. Further, a dummy chip 130 means a semiconductor chip that does not have any electrical function.

FIG. 1 is an explanatory diagram of the Cow structure of the chip of the solid-state imaging device 100 according to the present disclosure. On a wafer 510 of solid-state imaging element chips 110, a plurality of the solid-state imaging element chips 110 is formed in a grid pattern by a semiconductor process, as illustrated in FIG. 1. From a wafer 520 of logic chips 120A manufactured by another semiconductor process, a logic chip 120A that has been confirmed to be a non-defective product by inspection and been singulated is then bonded to a predetermined position of a predetermined solid-state imaging element chip 110 that has been confirmed to be a non-defective product on the wafer 510.

Likewise, from a wafer 521 of memory chips 120B, a memory chip 120B that has been confirmed to be a non-defective product by inspection and been singulated is bonded to a predetermined position of a predetermined solid-state imaging element chip 110 that has been confirmed to be a non-defective product on the wafer 510.

Likewise, from a wafer 530 of dummy chips 130, a dummy chip 130 that has been confirmed to be a non-defective product by inspection and been singulated is also bonded to a predetermined position of a predetermined solid-state imaging element chip 110 that has been confirmed to be a non-defective product on the wafer 510. The same applies in a case with a wafer 531 of processor chips 131 described later (neither is illustrated in the drawing). Note that, in FIG. 1, a chip on the wafer 510 marked with “x” is a defective chip 110n. Therefore, any active chip 120 such as the logic chip 120A is not bonded to the defective chip 110n.

FIG. 2 is a diagram illustrating a state in which a total of four chips of the three types of a logic chip 120A, a memory chip 120B, and dummy chips 130 and 130 are bonded to one of the solid-state imaging element chips 110 that have been formed on the wafer 510 and been confirmed to be non-defective. In this drawing, the wafer 510 shown in FIG. 1 is placed upside down. A state in which the logic chip 120A, the memory chip 120B, and the dummy chips 130 and 130 are bonded to the lower surface of the solid-state imaging element chip 110 is as illustrated in this drawing. After the bonding, each of these chips is then singulated along scribed lines 109.

However, with the recent evolution of the semiconductor manufacturing technology, active chips 120 such as the logic chip 120A and the memory chip 120B have been becoming smaller in size more rapidly than the solid-state imaging element chips 110. Because of this, the regions not covered with the active chips 120 have been becoming larger on the lower surfaces of the solid-state imaging element chips 110.

### Configuration of a Basic Form of a First Embodiment

A first embodiment aims to alleviate the impact of wire bonding at the time of mounting, and thus prevent appearance of cracks in a solid-state imaging element chip 110 formed with such a CoW structure. Also, appearance of warpage of the solid-state imaging element chip 110 is prevented, and the influence on imaging characteristics is reduced.

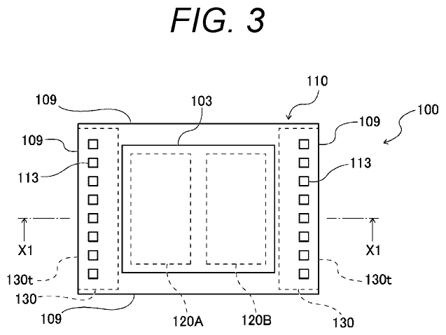

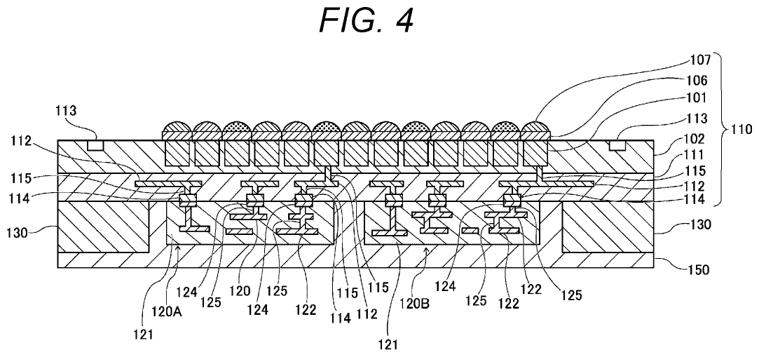

In the description below, a basic form of the first embodiment of the solid-state imaging device 100 according to the present disclosure will be described with reference to FIGS. 3 and 4. FIG. 3 is a plan view illustrating a schematic structure of the basic form of the first embodiment of the solid-state imaging device 100 according to the present disclosure. As illustrated in FIG. 3, a chip of the solid-state imaging device 100 is formed in a substantially rectangular shape in a planar view.

Further, a pixel region 103 having a substantially rectangular shape is formed on the upper surface. In the pixel region 103, photoelectric conversion units 101 that photoelectrically convert received imaging light for the respective pixels are formed so that an image signal is generated. Furthermore, electrode pads 113 for wire bonding connection to electrode pads (not illustrated) of an interposer substrate are formed with gold (Au) wires or the like at the left and right ends of the pixel region 103.

FIG. 4 is an X1-X1 cross-sectional end view illustrating a schematic structure of the basic form of the first embodiment of the solid-state imaging device 100 according to the present disclosure. As illustrated in the drawing, a chip of the solid-state imaging device 100 is formed by bonding a logic chip 120A in which a logic circuit including a drive element that processes an imaging signal, a wiring layer, and the like is disposed, and a memory chip 120B that accumulates pixel data and the like to the lower surface of a solid-state imaging element chip 110.

As illustrated in FIG. 4, in a solid-state imaging element chip 110, a photoelectric conversion unit 101 formed with a plurality of photodiodes is formed in a photodiode formation layer 102, for example. A color filter 106 is then stacked on the upper surface of the photoelectric conversion unit 101 on the imaging-light incident surface side of the solid-state imaging element chip 110, and an on-chip lens 107 is stacked on the upper surface thereof.

Note that an insulating film may be formed and planarized on the upper surface of the on-chip lens 107, and a light-transmissive substrate such as glass, for example, may be bonded to the upper surface via a bonding resin (both are not illustrated in the drawing).

A photodiode wiring layer 111 is formed by sequentially stacking an oxide film that is an insulator, and a wiring line 112 in which a wiring pattern is formed with a conductive metal such as copper (Cu) on the lower surface of the photoelectric conversion unit 101. That is, the wiring line 112 is interposed and stacked between an oxide film and an oxide film that are base members of the photodiode wiring layer 111.

Further, the photoelectric conversion unit 101 and the wiring line 112, and the wiring line 112 and a terminal 114 formed on the lower surface of the photodiode wiring layer 111 are connected by vias 115 and 115, respectively. As a result, pixel data generated by the photoelectric conversion unit 101 is connected to the terminal 114 sequentially through the via 115, the wiring line 112, and the via 115.

The logic chip 120A is a substrate for forming a logic circuit for sequentially reading pixel data generated in the respective pixels of the photoelectric conversion unit 101. The logic circuit includes a vertical drive unit, a horizontal drive unit, a system control unit, a signal processing unit, and the like (all not illustrated in the drawing), and the logic circuit is connected in a wiring layer 121, for example.

Like the photodiode wiring layer 111, the logic chip 120A is formed by sequentially stacking a wiring line 122 in which a wiring pattern is formed with a conductive metal such as copper (Cu) and an oxide film. The wiring line 122 in an upper layer and the wiring line 122 in a lower layer are then connected by a via 125. Further, the wiring line 122 in the upper layer is connected to the terminal 124 formed on the upper surface of the logic chip 120A by the via 125.

A terminal 124 of the logic chip 120A is made to face the bonding surface of the terminal 114 of the photodiode wiring layer 111, and is Cu—Cu connected thereto. As a result, pixel data generated in the photoelectric conversion unit 101 is connected to the terminal 124 of the wiring layer 121 of the logic chip 120A through the wiring line 112, the via 115, and the terminal 114 of the photodiode wiring layer 111, and is connected to the wiring line 122 of the wiring layer 121.

Like the logic chip 120A, the memory chip 120B is also formed by sequentially stacking the wiring line 122 in which a wiring pattern is formed with a conductive metal such as copper (Cu) and an oxide film. The wiring line 122 in an upper layer and the wiring line 122 in a lower layer are then connected by a via 125. Further, the wiring line 122 in the upper layer is connected to the terminal 124 formed on the upper surface of the logic chip 120A by the via 125.

The terminal 124 of the memory chip 120B is made to face the bonding surface of the terminal 114 of the photodiode wiring layer 111, and is Cu—Cu connected thereto. As a result, pixel data generated in the photoelectric conversion unit 101 is connected to the terminal 124 of the wiring layer 121 of the memory chip 120B through the wiring line 112, the via 115, and the terminal 114, and is electrically connected to the wiring line 122 of the wiring layer 121.

In this manner, the logic chip 120A and the memory chip 120B are electrically connected to the lower surface of the photodiode wiring layer 111 of the solid-state imaging element chip 110 by Cu—Cu connection via the terminal 114 and the terminal 124.

The logic chip 120A and the memory chip 120B Cu—Cu connected to the lower surface of the photodiode wiring layer 111 are covered with an insulating film 150. Thus, the logic chip 120A and the memory chip 120B are electrically insulated, and are protected so as not to be mechanically damaged.

An input/output signal of the logic circuit formed with the wiring line 122 of the logic chip 120A is connected to electrode pads 113 formed at both ends or peripheral ends of the upper surface of the solid-state imaging element chip 110 via a TSV (not illustrated), Cu—Cu connection (not illustrated), or the like. The electrode pads 113 are electrically connected, by wire bonding, for example, to electrode pads (not illustrated) of the interposer substrate disposed in the package of the solid-state imaging device 100.

On the lower surfaces of the electrode pads 113, dummy chips 130 connecting the lower surfaces of the adjacent solid-state imaging element chips 110 and 110 are bonded in a mode having end surfaces 130t in the same plane as the cutting plane of the solid-state imaging element chip cut out from the wafer. That is, as illustrated in FIG. 3, the dummy chips 130 are joined in a manner of connecting the lower surfaces of the adjacent solid-state imaging element chips 110 and 110 and crossing the entire region of the lower surfaces of the electrode pads 113, and are then singulated together with the solid-state imaging element chip 110. As the dummy chips 130 are singulated, side surfaces that are the cutting planes of the dummy chips 130 turn into the end surfaces 130t that are in the same plane as the cutting plane of the solid-state imaging element chip 110. Note that the cutting plane of the solid-state imaging element chip 110 is mainly the cutting planes of the photodiode formation layer 102 and the photodiode wiring layer 111.

Accordingly, the regions to which the dummy chips 130 are joined serve as the scribed lines 109 at the time of dicing. The dummy chips 130 are semiconductor chips having no electrical functions, and are formed with silicon, for example.

The insulating film 150 covers the peripheral side surfaces of the logic chip 120A and the memory chip 120B, the gap between the logic chip 120A and the memory chip 120B, and the lower surfaces thereof, so as to bury these surfaces and gap. Also, the insulating film 150 covers the entire region of the lower surface of the solid-state imaging element chip 110 to which the logic chip 120A and the memory chip 120B are not bonded.

The outer shape of the insulating film 150 in a planar view is formed to be substantially the same as the outer shape of the solid-state imaging element chip 110, and the peripheral side surfaces of the insulating film 150 are formed in the same planes as the peripheral side surfaces of the solid-state imaging element chip 110. Further, the lower surface of the insulating film 150 covering the logic chip 120A and the memory chip 120B is planarized. Accordingly, a chip of the solid-state imaging device 100 is formed in a substantially rectangular shape as a whole.

The insulating film 150 includes an oxide film of silicon dioxide (SiO₂) or the like, an insulating resin 150a having insulating properties, and the like, for example.

The solid-state imaging element chip 110 of the solid-state imaging device 100 according to the basic form of the first embodiment is formed in a CoW structure on the wafer 510, and is then singulated, to have the configuration as described above. Note that explanation of the package of the solid-state imaging device 100 is not made herein.

Here, in a case where the dummy chips 130 are directly covered with the insulating film 150 of silicon dioxide or the like without being bonded to the lower surfaces of the electrode pads 113 of the solid-state imaging element chip 110, the regions of the scribed lines 109 are laminates including the solid-state imaging element chip 110 mainly formed with silicon and the insulating film 150. Therefore, the back surfaces (lower surfaces) of the electrode pads 113 disposed on the upper surface of the solid-state imaging element chip 110 in the vicinities of the scribed lines 109 are also laminates including the solid-state imaging element chip 110 and the insulating film 150. In this case, the silicon dioxide forming the insulating film 150 is a hard but non-viscous material, and therefore, might be cracked when the electrode pads 113 is subjected to the impact of wire bonding.

On the other hand, in the solid-state imaging element chip 110 of the solid-state imaging device 100 according to the basic form of the first embodiment, the dummy chips 130 formed with silicon, which is a material softer than silicon dioxide, are bonded to the lower surfaces of the electrode pads 113. After that, the active chips 120 and the dummy chips 130 are covered with the insulating film 150, so that the impact of wire bonding at the time of mounting can be alleviated. Thus, appearance of cracks can be prevented.

Furthermore, the dummy chips 130 formed with silicon, which is substantially the same material as the solid-state imaging element chip 110, are bonded to the lower surface of the solid-state imaging element chip 110. Accordingly, the difference in linear expansion coefficient between the upper surface of the solid-state imaging element chip 110 and the lower surface to which the dummy chips 130 are bonded is canceled out. Thus, the occurrence of warpage of the solid-state imaging element chip 110 can be prevented, and the influence on the imaging characteristics can be reduced.

### [Configuration of a First Modification of the First Embodiment

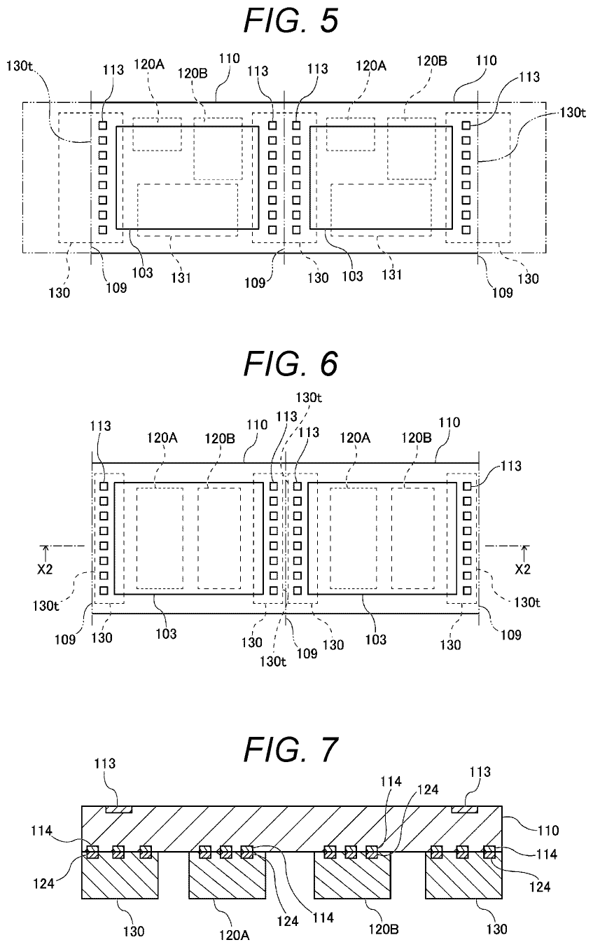

Next, the configuration of a first modification of the first embodiment is described. In the first modification, as illustrated in FIG. 5, the dummy chips 130 are bonded to the back surfaces of the electrode pads 113 of the solid-state imaging element chip 110 over the scribed lines 109, as in the basic form. However, the first modification differs from the basic form in that the processor chip 131 is further bonded to a free region of the bonding surface on which the logic chip 120A and the memory chip 120B are disposed.

Here, the processor chip 131 is a semiconductor chip that is neither the logic chip 120A nor the memory chip 120B and has an electrical function, and is included among the active chips 120. The processor chip 131 may be a chip having an electrical function such as a sensor edge processor (hereinafter referred to as “SEP”), for example. Incidentally, a sensor edge processor is a processor that preprocesses an enormous amount of pixel data from the solid-state imaging element chip 110 with high definition. Note that a dummy chip 130 may be bonded, instead of the processor chip 131. Other than the above, the configuration is similar to that of the basic form, and therefore, explanation thereof is not made herein.

As the first modification is designed as described above, the impact of wire bonding at the time of mounting can be alleviated, and appearance of cracks can be prevented, as in the basic form. Further, as the processor chip 131 is bonded to a free region in the region where the logic chip 120A and the memory chip 120B are disposed, the chip of the solid-state imaging device 100 is reinforced, and it is possible to secure strength and prevent the occurrence of warpage.

### [Configuration of a Second Modification of the First Embodiment

Next, the configuration of a second modification of the first embodiment is described. As illustrated in FIG. 6, the second modification differs from the basic form in that the dummy chips 130 or the processor chips 131 are bonded to the back surfaces of the electrode pads 113 of each solid-state imaging element chip 110 in a mode in which the dummy chips 130 or the processor chips 131 have planar end surfaces 130t adjacent to the cutting plane of the solid-state imaging element chip cut out from the wafer without crossing the scribed lines 109 as above.

As the second modification is designed as described above, the impact of wire bonding at the time of mounting can be alleviated, and appearance of cracks can be prevented, as in the basic form. Further, as the processor chips 131 or the dummy chips 130 are bonded to a free region in the region where the logic chip 120A and the memory chip 120B are disposed, the solid-state imaging element chip 110 is reinforced. Thus, strength can be enhanced, and the occurrence of warpage can be prevented.

Furthermore, in the second modification, singulation is not performed after the dummy chips 130 are bonded so as to cross the scribed lines 109 as in the basic form and the first modification. Accordingly, the active chips 120 such as the processor chips 131 having an electrical function can be bonded. It is of course possible to bond the dummy chips 130, instead of the processor chips 131. Other than the above, the configuration is similar to that of the basic form, and therefore, explanation thereof is not made herein.

[Configuration of a Third Modification of the First Embodiment]

Next, the configuration of a third modification of the first embodiment is described. A third modification to a sixth modification described later relate to modes for bonding the logic chip 120A, the memory chip 120B, the dummy chips 130, or the processor chip 131 to the lower surface of the solid-state imaging element chip 110. In the description below, FIGS. 7 to 10 will be described with reference to X2-X2 cross-sectional end views.

Among them, in the third modification and the fourth modification, the active chip 120 such as the logic chip 120A, the memory chip 120B, or the processor chip 131, and the dummy chips 130 are bonded to the lower surface of the solid-state imaging element chip 110 having the electrode pads 113 in the photodiode formation layer 102. That is, the present invention relates to bonding of the solid-state imaging element chip 110 having the electrode pads 113 in the photodiode formation layer 102.

Here, the bonding of the active chip 120 and the bonding of the dummy chips 130 to the lower surface of the solid-state imaging element chip 110 in the third modification are performed by Cu—Cu connection, as illustrated in FIG. 7. The third modification can be applied to the basic form described above, the first modification, or the second modification. Other than the above, the configuration is similar to that of the basic form, the first modification, or the second modification of the first embodiment, and therefore, explanation thereof is not made herein.

### Configuration of a Fourth Modification of the First Embodiment

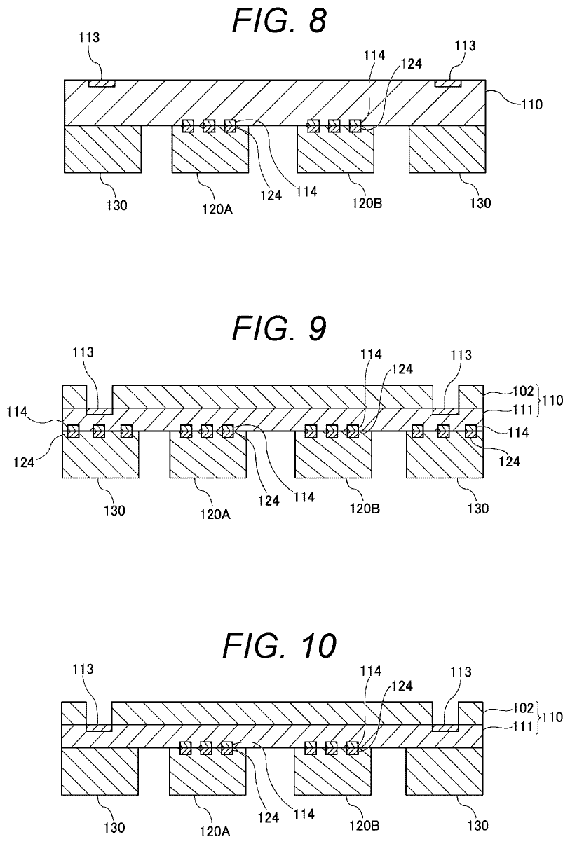

In the fourth modification, the active chip 120 is bonded to the lower surface of the solid-state imaging element chip 110 by Cu—Cu connection, as illustrated in FIG. 8. Furthermore, bonding of the dummy chips 130 is by bonding of insulating films such as oxide films. The fourth modification can be applied to the basic form described above, the first modification, or the second modification. Other than the above, the configuration is similar to that of the basic form, the first modification, or the second modification of the first embodiment, and therefore, explanation thereof is not made herein.

### Configuration of a Fifth Modification of the First Embodiment

Among them, in the fifth modification and the sixth modification, the active chip 120 such as the logic chip 120A, the memory chip 120B, or the processor chip 131, and the dummy chips 130 are bonded to the lower surface of the solid-state imaging element chip 110 having the electrode pads 113 in the photodiode wiring layer 111. That is, the present invention relates to bonding of the solid-state imaging element chip 110 having the electrode pads 113 in the photodiode wiring layer 111.

Here, the bonding of the active chip 120 and the bonding of the dummy chips 130 to the lower surface of the solid-state imaging element chip 110 in the fifth modification are performed by Cu—Cu connection, as illustrated in FIG. 9. The fifth modification can be applied to the basic form, the first modification, or the second modification of the first embodiment described above. Other than the above, the configuration is similar to that of the basic form, the first modification, or the second modification, and therefore, explanation thereof is not made herein.

### Configuration of a Sixth Modification of the First Embodiment

In the sixth modification, the active chip 120 is bonded to the lower surface of the solid-state imaging element chip 110 by Cu—Cu connection, as illustrated in FIG. 10. Furthermore, bonding of the dummy chips 130 is by bonding of insulating films such as oxide films. The sixth modification can be applied to the basic form, the first modification, or the second modification of the first embodiment described above. Other than the above, the configuration is similar to that of the basic form, the first modification, or the second modification, and therefore, explanation thereof is not made herein.

### 2. Method for Manufacturing the First Embodiment of a Solid-State Imaging Device According to the Present Disclosure

FIG. 11 is a diagram for explaining a process of coating the solid-state imaging element chip 110 to which the active chip 120 and the dummy chips 130 are bonded with the insulating film 150, and singulating the solid-state imaging element chip 110 according to a method for manufacturing the first embodiment of the solid-state imaging device 100 according to the present disclosure.

First, as illustrated in FIG. 11A, the logic chip 120A, the memory chip 120B, and the dummy chips 130 are bonded to the lower surface of the photodiode wiring layer 111 of the solid-state imaging element chip 110 formed on the wafer 510. This state is a diagram of the state in which the steps illustrated in FIGS. 1 and 2 have been completed.

Next, as illustrated in FIG. 11B, the insulating film 150 is stacked on the surface of the lower surface of the photodiode wiring layer 111 of the solid-state imaging element chip 110 to which the logic chip 120A, the memory chip 120B, and the dummy chips 130 are bonded. As a result, the logic chip 120A, the memory chip 120B, and the dummy chips 130 are covered with the insulating film 150.

In this state, however, the insulating film 150 is stacked in conformity with the shapes of the irregularities of the logic chip 120A, the memory chip 120B, and the dummy chips 130, and therefore, the surface thereof is in an uneven state.

To counter this, the lower surface of the insulating film 150 is polished by chemical mechanical polisher (CMP (hereinafter referred to as “CMP”)), as illustrated in FIG. 11 C. As a result, the insulating film 150 is planarized and thinned.

In this CMP, the insulating film 150 remains thin so as to cover the entire lower surfaces of the active chip 120 and the dummy chips 130.

Next, as illustrated in FIG. 11D, a support substrate 160 is bonded to the lower surface of the insulating film 150. Next, as illustrated in FIG. 11E, the upper surface of the wafer 510 is thinned by CMP or the like.

Next, as illustrated in FIG. 11F, the color filter 106, the on-chip lens 107, and the like are mounted on the upper surface of the photodiode formation layer 102 of the thinned solid-state imaging element chip 110. The electrode pads 113 for wire bonding connection are then formed at predetermined positions on the upper surface of the photodiode formation layer 102. The scribed lines 109 are formed between the electrode pads 113 and the electrode pads 113 of the adjacent solid-state imaging element chips 110.

Next, as illustrated in FIG. 11G, the wafer 510 is cut along the scribed lines 109 so that singulation is performed. The singulation may be performed by removing the support substrate 160 from the insulating film 150, and attaching a protective dicing sheet 170 (not illustrated) to the lower surface of the insulating film 150. Alternatively, it may be performed without removing the support substrate 160.

The dicing is performed using a device called a dicer including a blade 175 described later. The blade 175 is a disk-shaped grindstone, and is provided so as to be able to rotate about a predetermined rotation shaft 175a. That is, the depth position of the blade 175 with respect to a scribed line 109 is adjusted, and the upper surface side of the wafer 510 is linearly cut out for singulation at a predetermined depth by the rotating blade 175, so that the chip of the solid-state imaging device 100 can be obtained.

The chip of the solid-state imaging device 100 obtained by the manufacturing process as described above is packaged and inspected. Thus, the solid-state imaging device 100 according to the first embodiment of the present disclosure can be manufactured.

### 3. Second Embodiment of a Solid-State Imaging Device According to the Present Disclosure

### Configuration of a Basic Form of a Second Embodiment

In a second embodiment, insufficient planarization of the steps generated when an active chip 120 bonded to the lower surface of a solid-state imaging element chip 110 formed with a CoW structure is covered with the insulating film 150 is solved, and defective bonding to a support substrate 160 is prevented.

Also, it is intended to reduce the influence of distortion caused by the difference in linear expansion coefficient between the active chip 120 and the insulating film 150 on the photoelectric conversion characteristics. For this reason, in the basic form of the second embodiment, a dummy chip 130 is bonded to a free region to which the active chip 120 is not bonded.

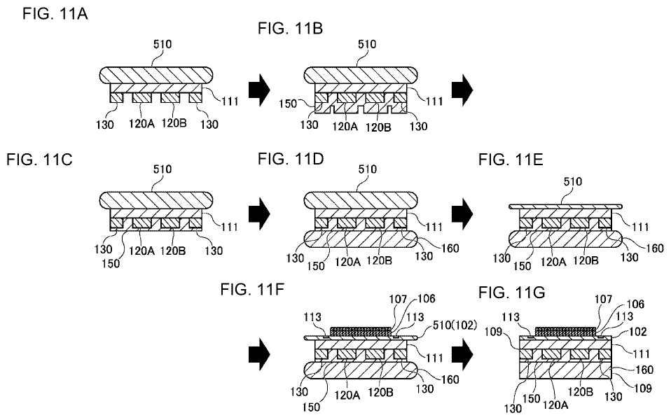

In the description below, the basic form of the second embodiment of a solid-state imaging device 100 according to the present disclosure will be described with reference to FIGS. 12 and 13.

FIG. 12A is a Y1-Y1 cross-sectional end view illustrating a first example of a schematic structure of the basic form of the second embodiment of a chip of the solid-state imaging device 100 according to the present disclosure. Further, FIG. 12B is a bottom view thereof. As illustrated in FIG. 12B, a chip of the solid-state imaging device 100 is formed in a substantially rectangular shape in a bottom view. A logic chip 120A is then bonded to the left side of the lower surface of the solid-state imaging element chip 110, and a memory chip 120B is bonded to the right side. A dummy chip 130 is then bonded to the free region between the logic chip 120A and the memory chip 120B.

FIG. 13A is a Y1-Y1 cross-sectional end view illustrating a second example of a schematic structure of the basic form of the second embodiment of the solid-state imaging device 100 according to the present disclosure. Further, FIG. 13B is a bottom view thereof. As illustrated in FIG. 13B, in the chip of the solid-state imaging device 100, the memory chip 120B is bonded to substantially the center of the lower surface of the solid-state imaging element chip 110. The dummy chips 130 are then bonded to the free regions to the right and the left of the memory chip 120B.

The dummy chips 130 are formed with silicon, for example. Alternatively, other than silicon, the dummy chips 130 may be formed with aluminum oxide (Al₂O₃), silicon carbide (Sic), aluminum nitride (AlN), silicon nitride (Si₃N₄), titanium (Ti), titanium nitride (TiN), carbon (C), silicon carbonitride (SiCN), polysilicon, or tantalum nitride (TaN), for example.

The configuration of the basic form of the second embodiment other than the above aspects is similar to that of the first embodiment described with reference FIGS. 3 and 4, and therefore, explanation thereof is not made herein.

### Effects of the Basic Form of the Second Embodiment

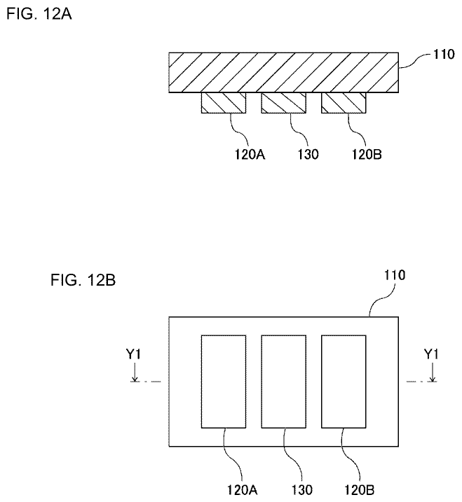

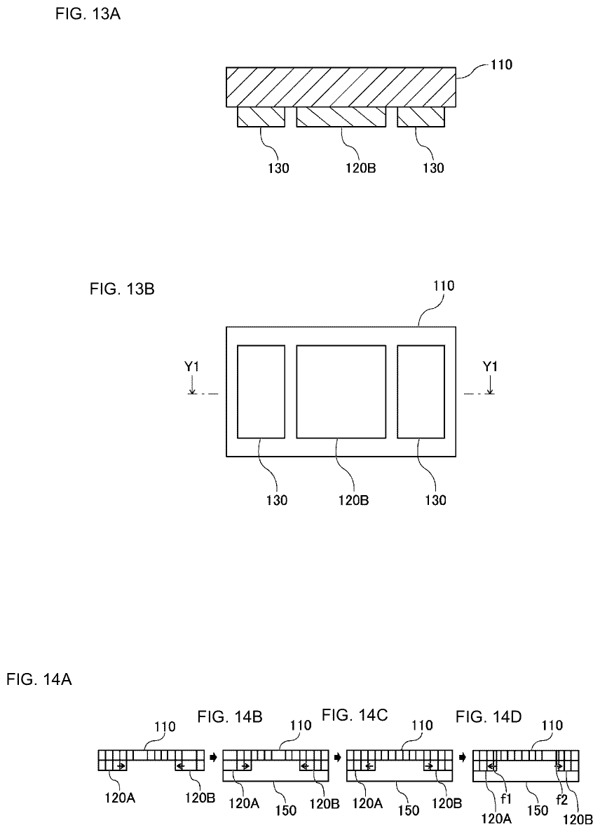

Next, a first effect of the basic form of the second embodiment is described below. FIG. 14 is a partially enlarged view corresponding to a Y1-Y1 cross-sectional end view illustrating a comparative example in a case where any dummy chip 130 is not bonded in the example illustrated in FIG. 12.

Here, in a case where the insulating film 150 is a silicon dioxide film, the temperature of the solid-state imaging element chip 110, the logic chip 120A, and the memory chip 120B is raised to about 350° C. at the time of coating. Because of this, the logic chip 120A and the memory chip 120B each expand in the direction of an arrow as illustrated in FIG. 14A.

Next, in the step of coating with the insulating film 150 such as a silicon dioxide film, the temperature is maintained at about 350° C. Accordingly, the chips remaining in the expanded shapes are covered with the insulating film 150, as illustrated in FIG. 14B.

Next, when the coating with the insulating film 150 is completed, and cooling is performed, the logic chip 120A and the memory chip 120B each try to contract in the direction of an arrow as illustrated in FIG. 14C. However, the linear expansion coefficient of the insulating film 150 such as a silicon dioxide film is smaller than that of silicon, and therefore, the logic chip 120A and the memory chip 120B are secured by the insulating film 150.

Because of this, a stress f1 is generated in the contraction direction in the logic chip 120A, and a stress f2 is generated in the contraction direction in the memory chip 120B, as illustrated in FIG. 14D. These stresses f1 and f2 act as tensile stresses.

As a result, these stresses f1 and f2 are also transferred to the solid-state imaging element chip 110 bonded to the upper surfaces of the logic chip 120A and the memory chip 120B, and tensile stresses act in the directions of the stresses f1 and f2. Because of this, distortion occurs in the solid-state imaging element chip 110, and the mobility of electrons and holes specifically fluctuates. In particular, the characteristics of the transistors disposed at the ends of these active chips 120 fluctuate, and therefore, any circuit cannot be disposed near the ends of the active chips 120. Furthermore, this causes alignment deviation when the on-chip lens 107 on the upper surface of the solid-state imaging element chip 110 is installed.

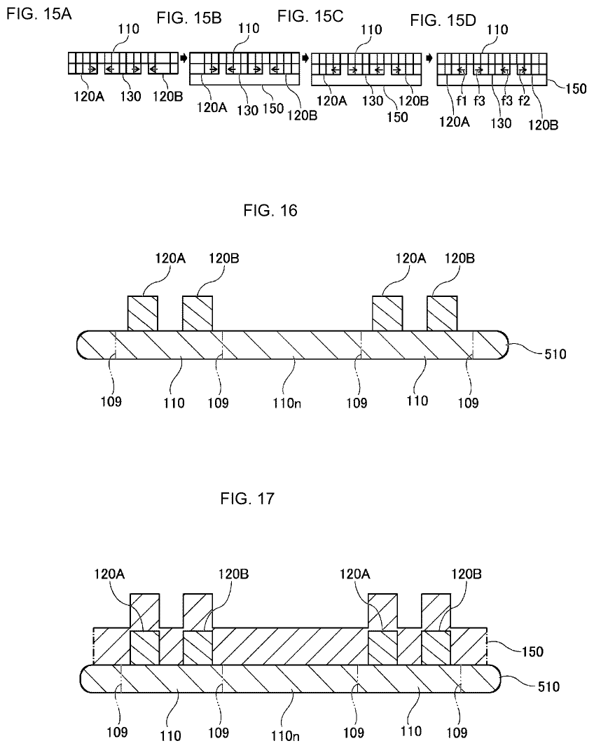

In the basic form of the second embodiment, on the other hand, as illustrated in FIG. 15, the dummy chips 130 are disposed and bonded between the logic chip 120A and the memory chip 120B, to alleviate the tensile stresses f1 and f2. Specifically, as illustrated in FIG. 15A, a dummy chip 130 formed with silicon is bonded between the logic chip 120A and the memory chip 120B. Each of these chips is heated to about 350° C. when covered with the insulating film 150 such as a silicon dioxide film, and thus, the respective chips expand in the directions of arrows. The chips remaining in the expanded shapes are then covered with the insulating film 150 and are secured, as illustrated in FIG. 15B.

As the coating with the insulating film 150 is completed, and cooling is performed, the logic chip 120A and the memory chip 120B each try to contract in the direction of an arrow as illustrated in FIG. 15C. Likewise, the dummy chip 130 also tries to contract in the directions of arrows. However, the arrow directions in which the logic chip 120A and the memory chip 120B are to contract are the opposite to the arrow directions in which the dummy chip 130 is to contract. Moreover, since these chips are secured by the insulating film 150, as illustrated in FIG. 15D, the stress f1 is generated in the logic chip 120A, the stress f2 is generated in the memory chip 120B, and stresses f3 and f3 are generated in the dummy chip 130.

These stresses f1 and f2, and f3 and f3 act as tensile stresses. Moreover, since the stresses f1 and f3, and the stresses f2 and f3 act in opposite directions, the stresses f1 and f3, and the stresses f2 and f3 cancel each other out, and only the difference between the stresses f1 and f3, and the difference between the stresses f2 and f3 acts as tensile stresses.

As a result, the tensile stresses of the offset differences between these stresses f1 and f3, and f2 and f3 also act on the solid-state imaging element chip 110 bonded to the upper surfaces of the logic chip 120A, the memory chip 120B, and the dummy chip 130. Since the stresses f1 and f3, and f2 and f3 in the opposite directions are canceled each other out, the influence of the tensile stresses transferred to the solid-state imaging element chip 110 bonded to the upper surfaces of the logic chip 120A and the memory chip 120B can be reduced. Accordingly, distortion to be generated in the solid-state imaging element chip 110 can be reduced, and fluctuations in the characteristics of the transistors can be prevented. Thus, circuits can be disposed in the vicinities of the ends of these active chips 120.

Note that the expansion/contraction length due to the generated distortion can be derived by the following formula regarding linear expansion.

ΔL=α×L×ΔT

Here, ΔL represents the expansion/contraction length, xx represents the linear expansion coefficient, L represents the length of the chip, and ΔT represents the temperature rise value.

Accordingly, where the expansion/contraction length of the logic chip 120A is ΔLLog, and the expansion/contraction length of the dummy chip 130 is ΔLDum, for example, ΔLLog=ΔLDum is satisfied, so that the distortion is canceled out. That is, it is only required to satisfy

αlog×L Log×ΔT=αDum×LDum×ΔT.

Here, the logic chip 120A and the dummy chip 130 have the same ΔT, and therefore, it is only required to satisfy

ΔLog×L Log=αDum×LDum.

From the above formula, the shapes and the materials of the logic chip 120A, the memory chip 120B, and the dummy chip 130 are appropriately selected so that the difference in stress and the distortion to be generated in the solid-state imaging element chip 110 can be made zero (0).

Material considered to be usable as the dummy chip 130 are shown in Table 1. As the dummy chip 130, a material having physical properties with a linear expansion coefficient close to that of the solid-state imaging element chip 110 is desirable. Accordingly, as can be seen from Table 1, other than silicon (Si), aluminum oxide (Al₂O₃), silicon carbide (Sic), aluminum nitride (AlN), silicon nitride (Si₃N₄), titanium (Ti), titanium nitride (TiN), carbon (C), silicon carbonitride (SiCN), polysilicon, or tantalum nitride (TaN) is suitable, for example.

Also, as can be seen from Table 1, when the dummy chip 130 is formed, it is only required to select a material that has a linear expansion coefficient suitable for the dummy chip 130, has a thermal conductivity suitable for the heat dissipation described later, and is suitable as a CMP stopper.

TABLE 1

| | | | | Suitability | |
|---|---|---|---|---|---|
| | Linear | | | as dummy | |
| | expansion | Suitability | Thermal | chip for | Suitability |
| | coefficient | as dummy | conductivity | heat | as CMP |
| Material | (ppm/K) | chip | (W/m · K) | dissipation | stopper |
| Solid-state | Around 5 | — | — | — | — |
| imaging element | | | | | |
| chip | | | | | |
| Silicon (Si) | 2.4 | ◯ | 168 | ◯ | ◯ |
| Silicon dioxide | 0.5 | X | 1.4 | X | X |
| (SiO₂) | | | | | |
| Copper (Cu) | 16.8 | X | 403 | ◯ | X |
| Aluminum oxide | 9 | ◯ | 35 | ◯ | ◯ |
| (Al₂O₃) | | | | | |
| Silicon carbide | 6.6 | ◯ | 350 | ◯ | ◯ |
| (SiC) | | | | | |
| Aluminum nitride | 5 | ◯ | 285 | ◯ | ◯ |
| (AlN) | | | | | |
| Silicon nitride | About 3 | ◯ | 100 | ◯ | ◯ |
| (Si₃N₄) | | | | | |
| Titanium (Ti) | 8.5 | ◯ | 17 | Δ | ◯ |
| Titanium nitride | 8 | ◯ | 29 | Δ | ◯ |
| (TiN) | | | | | |
| Aluminum (Al) | 23.9 | X | 204 | ◯ | ◯ |
| Carbon (C) | 4.3 | ◯ | 24 | Δ | ◯ |
| Silicon | 3 | ◯ | 200 | ◯ | ◯ |
| carbonitride | | | | | |
| (SiCN) | | | | | |
| Polysilicon | 3.43 | ◯ | 162 | ◯ | ◯ |
| (Poly-Si) | | | | | |
| Tantalum nitride | 9 | ◯ | 100 | ◯ | ◯ |
| (TaN) | | | | | |

◯: suitable,
Δ: slightly suitable,
X: not suitable
A predetermined insulating treatment is to be conducted in a case where insulation properties are required.

Next, a second effect of the basic form of the second embodiment is described below. FIG. 16 is a cross-sectional end view illustrating a comparative example in a case where any dummy chip 130 is not bonded in the example illustrated in FIG. 12, with the Y1-Y1 line of the wafer 510 being viewed from the opposite direction. Accordingly, the lower side in FIG. 16 is the wafer 510, and the logic chip 120A and the memory chip 120B are bonded above the wafer.

As illustrated in FIG. 16, the logic chips 120A and the memory chips 120B are bonded onto the wafer 510 of the solid-state imaging element chips 110. With the evolution of the semiconductor manufacturing technology, the active chips 120 are being reduced in size compared with the solid-state imaging element chips 110, and therefore, there exist free regions on the wafer 510 to which the active chips 120 are not bonded. On the wafer 510, there also exists a defective chip 110n determined to be a defective product by inspection.

When the insulating film 150 is laminated on these active chips 120 in such a state, the coating surface thereof is in an uneven shape in conformity with the thicknesses of the bonded active chips 120, as illustrated in FIG. 17.

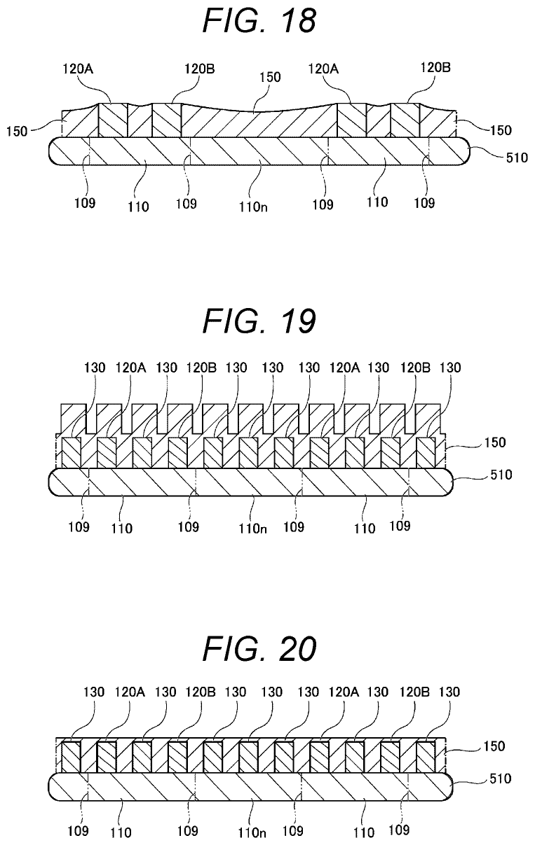

Next, polishing is performed by CMP to planarize the upper surface of the insulating film 150. As a result, the thickness of the portions of the insulating film 150 between the logic chips 120A and the memory chips 120B are made smaller, as illustrated in FIG. 18, for example. Moreover, the active chips 120 are not bonded to the defective chip 110n, and therefore, the thickness of the insulating film 150 is further reduced. In this manner, the central portion of the polished surface may be largely polished and recessed. This phenomenon is generally called “dishing”, because a cross-section of the polished surface is recessed at the central portion like a dish.

As a result, when the planarized surface of the insulating film 150 and the support substrate (not illustrated) are bonded to each other, there is a possibility that a bonding failure such as formation of a void will occur in the bonding surfaces of both the insulating film 150 and the support substrate due to insufficient planarization at the time of step filling planarization between the logic chip 120A and the memory chip 120B.

In the basic form of the second embodiment, on the other hand, the dummy chips 130 are bonded to the free regions between the logic chips 120A and the memory chips 120B, as illustrated in FIGS. 19 to 21. A predetermined number of dummy chips 130 are bonded to the defective chip 110n in this configuration. As a result, as illustrated in FIG. 19, it is possible to narrow the intervals of the irregularities caused in the surface of the insulating film 150 in the case of coating with the insulating film 150.

Also, with such a configuration, as illustrated in FIG. 20, the occurrence of a dishing phenomenon due to CMP can be prevented, and the polished surface can be planarized. Thus, it is possible to prevent a bonding failure with the support substrate (not illustrated) due to insufficient planarization between the logic chips 120A and the memory chips 120B.

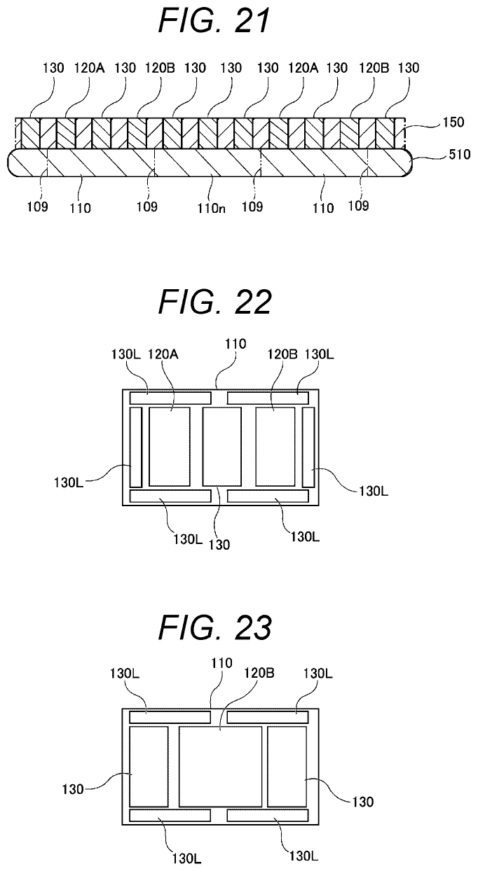

Further, the dummy chips 130 having a predetermined height are bonded so as to serve as stoppers against polishing by CMP, as illustrated in FIG. 21. Thus, when exposure of the dummy chips 130 by polishing is detected, CMP can be spontaneously stopped and completed. Furthermore, enhancement of in-plane uniformity, a reduction of process variation, simplification of process management in mass production, and an increase in yield can also be expected.

### Configuration of a First Modification of the Second Embodiment

A first modification relates to a solid-state imaging element chip 110 that has active chips 120 bonded to the lower surface in a Cow structure. In the solid-state imaging element chip 110, for example, dummy chips 130 and 130L having different shapes are bonded to free regions to which the active chips 120 are not bonded.

In the description below, the first modification of the second embodiment of the solid-state imaging device 100 according to the present disclosure will be described with reference to FIGS. 22 to 24. Note that end views corresponding to FIGS. 12A and 13A relating to the basic form described above are not provided herein.

FIG. 22 is a bottom view illustrating a first example of a schematic structure of the first modification of the second embodiment of the solid-state imaging device 100 according to the present disclosure. As illustrated in this drawing, in a chip of the solid-state imaging device 100, a logic chip 120A is bonded to the left side of the lower surface of the solid-state imaging element chip 110, and a memory chip 120B is bonded to the right side. A dummy chip 130 is then bonded to the free region between the logic chip 120A and the memory chip 120B. Also, as illustrated in the drawing, a plurality of strip-shaped dummy chips 130L is disposed and bonded onto the peripheries of the logic chip 120A, the dummy chip 130, and the memory chip 120B in such a manner as to surround these chips.

FIG. 23 is a bottom view illustrating a second example of a schematic structure of the first modification of the second embodiment of the solid-state imaging device 100 according to the present disclosure. As illustrated in this drawing, in a chip of the solid-state imaging device 100, the memory chip 120B is bonded to substantially the center of the lower surface of the solid-state imaging element chip 110. The dummy chips 130 are then bonded to the free regions to the right and the left of the memory chip 120B. Also, as illustrated in the drawing, a plurality of strip-shaped dummy chips 130L is disposed and bonded onto the peripheries of the memory chip 120B and the dummy chips 130 so as to fill these free regions.

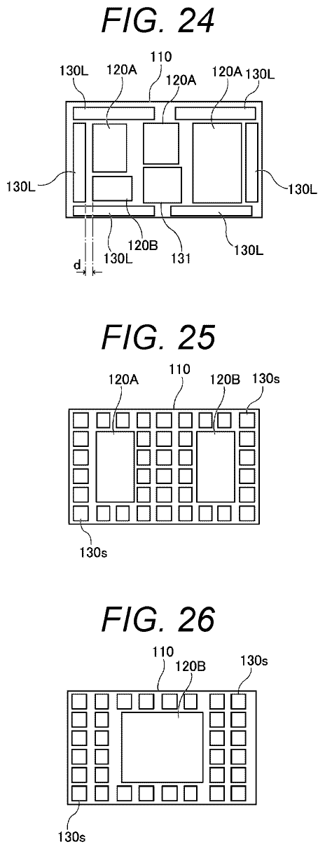

FIG. 24 is a bottom view illustrating a third example of a schematic structure of the first modification of the second embodiment of the solid-state imaging device 100 according to the present disclosure. As illustrated in this drawing, in a chip of the solid-state imaging device 100, three logic chips 120A, one memory chip 120B, and a processor chip 131 such as one SEP are bonded to the lower surface of the solid-state imaging element chip 110. Then, a plurality of strip-shaped dummy chips 130L is disposed and bonded in free regions around these active chips 120 and the processor chip 131 in such a manner as to surround the active chips 120 and the processor chip 131.

The dummy chips 130L are preferably bonded at a distance d from each end surface of the solid-state imaging element chip 110 and the active chips 120. Specifically, the distance d is desirably at least 0.5 μm or longer, and is 50 μm or shorter. Each dummy chip 130L is formed in a substantially strip-shaped rectangle having the minimum short side of a free region separated by the distance d as one side, and is disposed in each free region. By separating the dummy chips by 0.5 μm or more, an insulation distance can be ensured, and the dummy chips 130L can be easily bonded. This is common to the basic form of the second embodiment, the first modification, and the respective modifications described below.

The configuration of the first modification of the second embodiment other than the above aspects is similar to that of the first embodiment described with reference FIGS. 3 and 4, and therefore, explanation thereof is not made herein.

In the first modification of the second embodiment, the dummy chips 130L are disposed at the peripheral end portions of the lower surface of the solid-state imaging element chip 110 as described above, and thus, the peripheral end portions can be reinforced. Accordingly, as described in the basic form of the second embodiment, the distortion to be generated in the solid-state imaging element chip 110 can be further reduced, and fluctuations in the transistor characteristics can be prevented. Also, circuits can be disposed in the vicinities of the end portions of the solid-state imaging element chip 110.

Furthermore, as the dummy chip 130 is bonded, the occurrence of a dishing phenomenon can be prevented, and the insulating film 150 can be planarized by CMP. Further, CMP can be spontaneously stopped and completed, and enhancement of in-plane uniformity, a reduction of process variation, simplification of process management in mass production, and an increase in yield can also be expected.

### Configuration of a Second Modification of the Second Embodiment

A second modification relates to a solid-state imaging element chip 110 that has active chips 120 bonded to the lower surface in a CoW structure. In the solid-state imaging element chip 110, a plurality of rectangular and small dummy chips 130s is bonded to free regions to which the active chips 120 are not bonded.

In the description below, the second modification of the second embodiment of the solid-state imaging device 100 according to the present disclosure will be described with reference to FIGS. 25 to 27. Note that end views corresponding to FIGS. 12A and 13A relating to the basic form described above are not provided herein.

FIG. 25 is a bottom view illustrating a first example of a schematic structure of the second modification of the second embodiment of the solid-state imaging device 100 according to the present disclosure. As illustrated in this drawing, in a chip of the solid-state imaging device 100, a logic chip 120A is bonded to the left side of the lower surface, and a memory chip 120B is bonded to the right side. Further, as illustrated in the drawing, in the free region between the logic chip 120A and the memory chip 120B, and in the periphery, a plurality of rectangular and small dummy chips 130s is disposed and bonded so as to fill the free region and the periphery in such a manner to surround these chips 120A and 120B.

FIG. 26 is a bottom view illustrating a second example of a schematic structure of the second modification of the second embodiment of the solid-state imaging device 100 according to the present disclosure. As illustrated in this drawing, in a chip of the solid-state imaging device 100, the memory chip 120B is bonded to substantially the central portion of the lower surface of the solid-state imaging element chip 110. Further, as illustrated in the drawing, in the free regions to the left and the right of the memory chip 120B, and in the periphery, a plurality of rectangular and small dummy chips 130s is disposed and bonded so as to fill the free regions and the periphery in such a manner to surround the memory chip 120B.

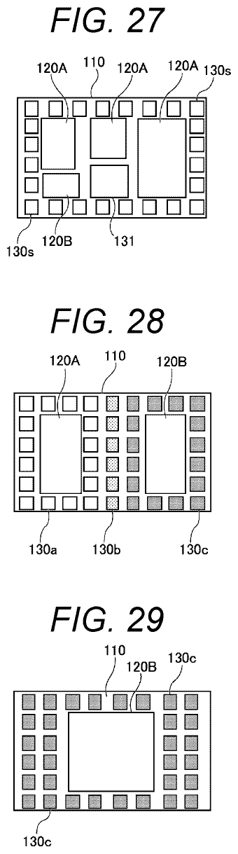

FIG. 27 is a bottom view illustrating a third example of a schematic structure of the second modification of the second embodiment of the solid-state imaging device 100 according to the present disclosure. As illustrated in this drawing, in a chip of the solid-state imaging device 100, three logic chips 120A, one memory chip 120B, and a processor chip 131 such as one SEP are bonded to the lower surface of the solid-state imaging element chip 110. Further, as illustrated in the drawing, in the free regions in the peripheries of these active chips 120, a plurality of rectangular and small dummy chips 130s is disposed and bonded so as to fill the free regions in the periphery in such a manner to surround these active chips 120.

Furthermore, in FIGS. 25 to 27, each dummy chip 130s is formed in a substantially square shape that has, as one side, the minimum short side of a free region at a distance of at least 0.5 μm or longer from each end surface of the solid-state imaging element chip 110 and the active chips 120. Further, while a distance of 0.5 μm or longer is ensured, the dummy chips 130s are bonded to the free regions.

The configuration of the second modification of the second embodiment other than the above aspects is similar to that of the first embodiment described with reference FIGS. 3 and 4, and therefore, explanation thereof is not made herein.

As the second modification of the second embodiment has a multiple dummy chip structure as described above, the dummy chips 130s can be thoroughly bonded to even small free regions. Thus, the effects similar to those described regarding the basic form of the second embodiment can be further improved.

### Configuration of a Third Modification of the Second Embodiment

A third modification relates to a solid-state imaging element chip 110 that has active chips 120 bonded to the lower surface in a CoW structure. In the solid-state imaging element chip 110, for example, dummy chips 130a, 130b, and 130c having material physical properties optimum for each active chip 120 are bonded to free regions to which the active chips 120 are not bonded. The material physical properties are the linear expansion coefficient, the thermal conductivity, and the like, for example.

In the description below, the third modification of the second embodiment of the solid-state imaging device 100 according to the present disclosure will be described with reference to FIGS. 28 to 30. Note that end views corresponding to FIGS. 12A and 13A relating to the basic form described above are not provided herein.

FIG. 28 is a bottom view illustrating a first example of a schematic structure of the third modification of the second embodiment of the solid-state imaging device 100 according to the present disclosure. As illustrated in this drawing, in a chip of the solid-state imaging device 100, a logic chip 120A is bonded to the left side of the lower surface, and a memory chip 120B is bonded to the right side. Further, as illustrated in the drawing, in the periphery of the logic chip 120A, a plurality of rectangular and small dummy chips 130a having physical properties a is disposed and bonded so as to fill the free regions in the periphery in such a manner to surround the logic chip 120A.

Likewise, as illustrated in the drawing, in the periphery of the memory chip 120B, a plurality of rectangular and small dummy chips 130c having physical properties c is also disposed and bonded so as to fill the free regions in the periphery in such a manner to surround the memory chip 120B.

Further, likewise, in a free region between the logic chip 120A and the memory chip 120B, a plurality of rectangular and small dummy chips 130b having physical properties b is arranged in a vertical line and are bonded.

FIG. 29 is a bottom view illustrating a second example of a schematic structure of the third modification of the second embodiment of the solid-state imaging device 100 according to the present disclosure. As illustrated in this drawing, in a chip of the solid-state imaging device 100, the memory chip 120B is bonded to substantially the central portion of the lower surface of the solid-state imaging element chip 110. Further, as illustrated in the drawing, in the free regions to the left and the right of the memory chip 120B, and in the periphery, a plurality of rectangular and small dummy chips 130c is disposed and bonded so as to fill the free regions and the periphery in such a manner to surround the memory chip 120B.

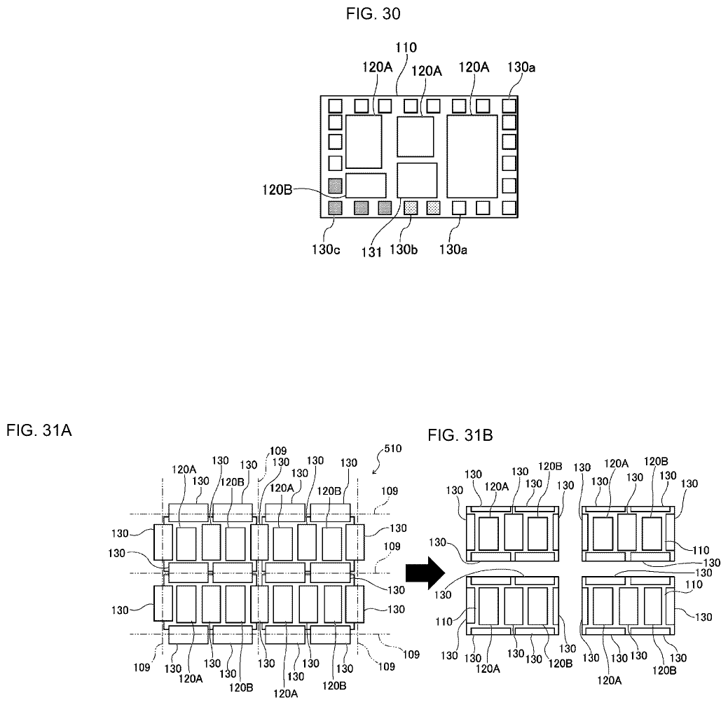

FIG. 30 is a bottom view illustrating a third example of a schematic structure of the third modification of the second embodiment of the solid-state imaging device 100 according to the present disclosure. As illustrated in this drawing, in a chip of the solid-state imaging device 100, three logic chips 120A, one memory chip 120B, and a processor chip 131 such as one SEP are bonded to the lower surface of the solid-state imaging element chip 110. Further, as illustrated in the drawing, in free regions in the peripheries of the three logic chips 120A, a plurality of rectangular and small dummy chips 130a having the physical properties a is disposed and bonded so as to fill the free regions and the peripheries.

Also, as illustrated in the drawing, in free regions in the vicinity of the processor chip 131, a plurality of rectangular and small dummy chips 130b having the physical properties b is disposed and bonded so as to fill the free regions in the vicinity.

Further, as illustrated in the drawing, in free regions in the vicinity of the memory chip 120B, a plurality of rectangular and small dummy chips 130c having the physical properties c is disposed and bonded so as to fill the free regions in the vicinity.

Furthermore, in FIGS. 28 to 30, the dummy chips 130a, 130b, and 130c are formed in a substantially square shape that has, as one side, the minimum short side of a free region at a distance of at least 0.5 μm or longer from each end surface of the solid-state imaging element chip 110 and the active chips 120, and are disposed in free regions.

The configuration of the third modification of the second embodiment other than the above aspects is similar to that of the first embodiment described with reference FIGS. 3 and 4, and therefore, explanation thereof is not made herein.

As the third modification of the second embodiment has a multiple dummy chip structure as described above, the dummy chips 130a, 130b, and 130c can be thoroughly bonded to even small free regions. Accordingly, as described regarding the basic form of the second embodiment, the shape and the linear expansion coefficient α of the dummy chips 130a, 130b, and 130c are appropriately selected so that the distortion to be generated in the solid-state imaging element chip 110 can be minimized. Also, the dummy chips 130a, 130b, and 130c are only required to be formed with an optimum physical material and have a shape that can minimize distortion, and are not limited to rectangular and small shapes. Further, the number of the dummy chips is not limited to any particular number.

### Configuration of a Fourth Modification of the Second Embodiment

A fourth modification relates to solid-state imaging element chips 110 that have active chips 120 bonded to the lower surfaces in a CoW structure. In the solid-state imaging element chips 110, dummy chips 130 are bonded to the regions of the scribed lines 109 and free regions to which the active chips 120 are not bonded.

In the description below, the fourth modification of the second embodiment of the solid-state imaging device 100 according to the present disclosure will be described with reference to FIGS. 31A and 31B. Note that end views corresponding to FIGS. 12A and 13A relating to the basic form described above are not provided herein.

FIG. 31A is a bottom view of solid-state imaging element chips 110 on a wafer 510, illustrating an example of a schematic structure of the fourth modification of the second embodiment of the solid-state imaging device 100 according to the present disclosure. As illustrated in this drawing, in each solid-state imaging element chip 110 on the wafer 510, a logic chip 120A is bonded to the left side, and a memory chip 120B is bonded to the right side. Further, as illustrated in the drawing, in the free region between the logic chip 120A and the memory chip 120B, and in the periphery, a plurality of rectangular dummy chips 130 is disposed and bonded so as to fill the free region and the periphery in such a manner to surround these active chips 120. In this case, between the adjacent solid-state imaging element chips 110 and 110, the dummy chips 130 are bonded over the scribed lines 109.

FIG. 31B is a diagram illustrating a state in which the wafer 510 described with reference to FIG. 31A has been diced into individual chips. In each singulated solid-state imaging element chip 110, each dummy chip 130 bonded over a scribed line 109 is divided into two by the scribed line 109, as illustrated in FIG. 31B. As a result, in each solid-state imaging element chip 110, a dummy chip 130 is bonded to the free region between the logic chip 120A and the memory chip 120B, and dummy chips 130 are also disposed and bonded to the regions of the scribed lines 109.

The configuration of the fourth modification of the second embodiment other than the above aspects is similar to that of the first embodiment described with reference FIGS. 3 and 4, and therefore, explanation thereof is not made herein.

As the fourth modification of the second embodiment is designed as described above, the number of dummy chips 130 can be reduced, in addition to the effects described regarding the basic form of the second embodiment. Furthermore, as the dummy chips 130 are bonded to the peripheral end surfaces of the solid-state imaging element chip 110, a guard ring effect (a mechanical protective effect for the peripheral end surfaces and the like of the solid-state imaging element chip 110) can also be provided.

### Configuration of a Fifth Modification of the Second Embodiment

A fifth modification relates to a solid-state imaging element chip 110 that has active chips 120 bonded to the lower surface. In this solid-state imaging element chip 110, dummy chips 130P and dummy films 130p acting as CMP stoppers are disposed and bonded. Specifically, the dummy chips 130P are bonded to a free region between active chips 120 on the lower surface of the solid-state imaging element chip 110, the regions of scribed lines 109, and the lower surface of a defective chip 110n. Other than that, the dummy films 130p are formed on the lower surfaces of the active chips 120, which are the surfaces opposite to the bonding surface with the solid-state imaging element chip.

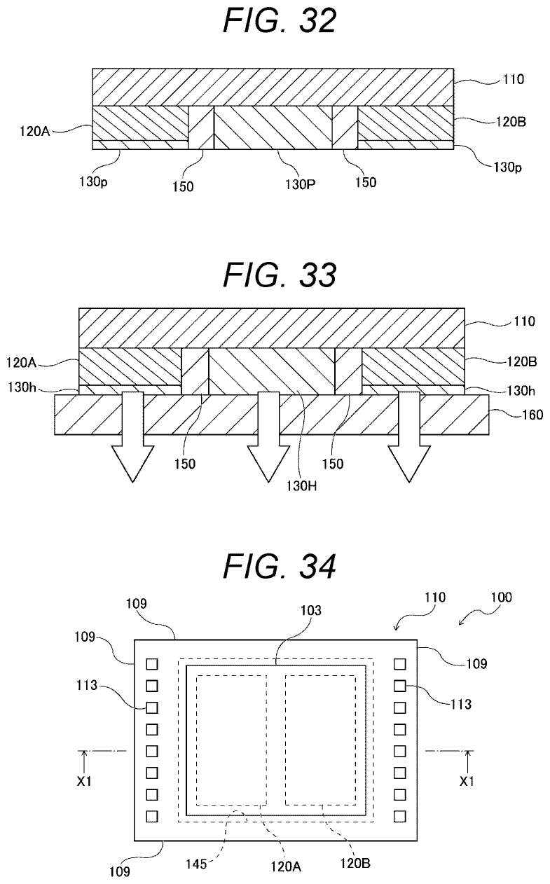

In the description below, the fifth modification of the second embodiment of the solid-state imaging device 100 according to the present disclosure will be described with reference to a Y1-Y1 cross-sectional end view shown in FIG. 32. Note that bottom views corresponding to FIGS. 12B and 13B relating to the basic form described above are not provided herein.

FIG. 32 is a diagram in which the fifth modification is applied to the example configuration illustrated in FIGS. 12A and 12B. As illustrated in FIG. 32, a logic chip 120A and a memory chip 120B are bonded to the lower surface of the solid-state imaging element chip 110, and a dummy chip 130P is bonded between the two chips. Further, dummy films 130p are formed on the lower surfaces of these active chips 120, and the lower surfaces of the dummy films 130p and the dummy chip 130 in this drawing act as CMP stoppers.

Here, as described above with reference to FIGS. 16 to 18, when coating with the insulating film 150 is performed in a state where any dummy chip 130 is not bonded to a region between the logic chip 120A and the memory chip 120B bonded to the solid-state imaging element chip 110, a dishing phenomenon occurs in the CMP process.

As a result, when the planarized surface of the insulating film 150 and the support substrate (not illustrated) are bonded to each other, there is a possibility that a bonding failure such as formation of a void will occur in the bonding surfaces of both the insulating film 150 and the support substrate due to insufficient planarization at the time of step filling planarization between the logic chip 120A and the memory chip 120B.

Therefore, in the fifth modification, as illustrated in FIG. 32, on the logic chip 120A and the memory chip 120B, the dummy films 130p functioning as CMP stoppers are formed on the lower surfaces that are the surfaces opposite to the surfaces of bonding to the solid-state imaging element chip 110. Further, instead of bonding a dummy chip 130, the dummy chip 130P functioning as a CMP stopper is bonded to the defective chip 110n.

To function as a CMP stopper, the dummy chip 130P needs to be formed with a material that is difficult to be polish. As the difficult-to-polish material, a material having such physical properties with which it is difficult to chemically polish is used, for example. The thickness, the torque, the temperature during polishing, and the like are monitored in the CMP process, and polishing is stopped when the polishing reaches the CMP stopper.

The dummy chip 130P and the dummy films 130p functioning as CMP stoppers are preferably formed with a material with physical properties including a polishing rate (removal rate) of 20 or more with respect to the silicon dioxide serving as the insulating film 150.

As shown in Table 1 mentioned above, a suitable material having such physical properties is silicon (Si), aluminum oxide (Al₂O₃), silicon carbide (Sic), aluminum nitride (AlN), silicon nitride (Si₃N₄), titanium (Ti), titanium nitride (TiN), aluminum (Al), carbon (C), silicon carbonitride (SiCN), polysilicon, or tantalum nitride (TaN), for example.

The configuration of the fifth modification of the second embodiment other than the above aspects is similar to that of the first embodiment described with reference FIGS. 3 and 4, and therefore, explanation thereof is not made herein.

As the fifth modification of the second embodiment is designed as described above, when the insulating film 150 is polished by CMP, the CMP can be stopped by detecting the point of time when the dummy chip 130P or the dummy films 130p are exposed.

The details of the CMP are similar to those described with reference to FIGS. 19 to 21 regarding the basic form of the second embodiment, and therefore, explanation thereof is not made herein.

### [Configuration of a Sixth Modification of the Second Embodiment

In a sixth modification, a solid-state imaging element chip 110 having active chips 120 bonded to the lower surface is bonded to a support substrate 160 via a dummy chip 130H formed with a single layer having a higher thermal conductivity than silicon dioxide as a heat transfer member, and dummy films 130h formed with multiple layers. With this arrangement, heat dissipation efficiency is increased. That is, the dummy chip 130H or the dummy films 130h include a heat transfer member stacked in a single layer or multiple layers formed with a material having a higher thermal conductivity than that of silicon dioxide.

In the description below, the sixth modification of the second embodiment of the solid-state imaging device 100 according to the present disclosure will be described with reference to a Y1-Y1 cross-sectional end view shown in FIG. 33. Note that bottom views corresponding to FIGS. 12B and 13B relating to the basic form described above are not provided herein.

FIG. 33 is a diagram in which the sixth modification is applied to the example configuration illustrated in FIGS. 12A and 12B. As illustrated in FIG. 33, a logic chip 120A and a memory chip 120B are disposed and bonded to the lower surface of the solid-state imaging element chip 110, and a dummy chip 130H is bonded between the two chips. Further, the dummy films 130h are stacked on the lower surfaces of these active chips 120, and are bonded to the support substrate 160 via the dummy films 130h and the dummy chip 130H.

Thus, heat generated in the active chips 120 such as the logic chip 120A and the memory chip 120B can be transferred to the support substrate 160 in the direction of arrow in this drawing via the dummy chip 130H and the dummy films 130h.

As the dummy chip 130H and the dummy films 130h, a material having a higher thermal conductivity than that of silicon dioxide, such as silicon (Si), copper (Cu), aluminum oxide (Al₂O₃), silicon carbide (Sic), aluminum nitride (AlN), silicon nitride (Si₃N₄), aluminum (Al), silicon carbonitride (SiCN), polysilicon, or tantalum nitride (TaN) is suitable as shown in Table 1 described above, for example.

The configuration of the sixth modification of the second embodiment other than the above aspects is similar to that of the first embodiment described with reference FIGS. 3 and 4, and therefore, explanation thereof is not made herein.

As the sixth modification of the second embodiment is designed as described above, it is possible to suppress a temperature rise in the active chips 120 such as the logic chip 120A and the memory chip 120B, increase reliability, and extend the life, in addition to the effects described regarding the basic form of the second embodiment.

Also, as the second embodiment is designed as described above, it is possible to solve insufficient planarization of the steps formed when the active chips 120 bonded to the lower surface of the solid-state imaging element chip 110 are covered with the insulating film 150, and prevent the occurrence of defective bonding to the support substrate 160.

Further, it is possible to reduce the influence of distortion caused by the difference in linear expansion coefficient between the active chips 120 and the insulating film 150 on the photoelectric conversion characteristics.

When the second embodiment is carried out, the basic form of the second embodiment and the first to sixth modifications may be combined as appropriate in accordance with the layout state of the solid-state imaging element chip 110 and the active chips 120.

### <4. Method for Manufacturing the Second Embodiment of a Solid-State Imaging Device According to the Present Disclosure>

A method for manufacturing the second embodiment of the solid-state imaging device 100 according to the present disclosure is substantially similar to that in the case of <2. Method for Manufacturing the First Embodiment of a Solid-State Imaging Device According to the Present Disclosure> described above, and therefore, explanation thereof is not made herein.

### <5. Third Embodiment of a Solid-State Imaging Device According to the Present Disclosure>

### Configuration of a Basic Form of a Third Embodiment

A third embodiment is to prevent the occurrence of warpage, and reduce influence on the imaging characteristics in a solid-state imaging device 100 formed with a CoW structure as described above.

Also, the third embodiment is designed to prevent the occurrence of cracks, chipping, and the like at the time of singulation, and thus, prevent quality degradation.

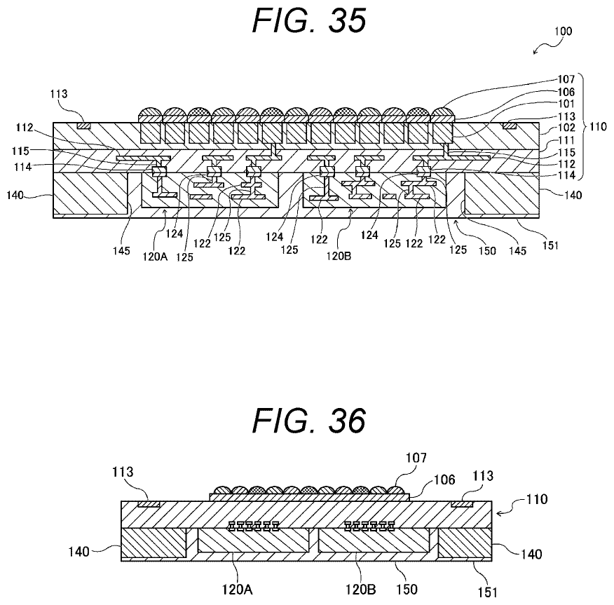

In the description below, a basic form of the third embodiment of a solid-state imaging device 100 according to the present disclosure will be described with reference to FIGS. 34 and 35. FIG. 34 is a plan view illustrating a schematic structure of the basic form of the third embodiment of the solid-state imaging device 100 according to the present disclosure. As illustrated in this drawing, a chip of the solid-state imaging device 100 is formed in a substantially rectangular shape in a planar view.

The shape of the basic form of the third embodiment in a plan view in FIG. 34 differs from that of the first embodiment in that a dug portion 145 is formed in the outer periphery of a logic chip 120A and a memory chip 120B bonded to the lower surface of a solid-state imaging element chip 110, and a silicon substrate 140 is disposed on the outer side of the dug portion 145.

As illustrated in an X1-X1 cross-sectional end view in FIG. 35, an insulating film 150 is formed on the inner side of the dug portion 145, and the logic chip 120A and the memory chip 120B are further disposed on the inner side of the insulating film 150. Further, the silicon substrate 140 is disposed on the outer side of the dug portion 145. That is, the outer peripheries of the logic chip 120A and the memory chip 120B are covered with the insulating film 150 in such a manner as to surround the chips, and the outer periphery and the lower surface thereof are further covered with the silicon substrate 140 in such a manner as to surround the outer periphery and the lower surface. Furthermore, on the lower surface of the silicon substrate 140, an insulating thin film 151 is thinly formed in the same plane as the lower surface of the insulating film 150.

The outer shape of the silicon substrate 140 in a planar view is formed in conformity with the outer shape of the solid-state imaging element chip 110, and the peripheral side surfaces of the silicon substrate 140 are formed substantially in the same planes as the peripheral side surfaces of the solid-state imaging element chip 110.

Accordingly, a chip of the solid-state imaging device 100 is formed in a substantially rectangular shape as a whole.

Other than the above, the configuration is similar to that in FIG. 4 illustrating the basic form of the first embodiment, and therefore, explanation thereof is not made herein.

Since the chips in the solid-state imaging device 100 according to the third embodiment are designed as described above, the regions of the scribed lines 109 at the time of dicing are formed as laminates of the solid-state imaging element chip 110 and the silicon substrate 140.

On the other hand, in a case where the silicon substrate 140 is not provided, and the peripheral side surfaces of the logic chip 120A and the memory chip 120B and the entire lower surface of the solid-state imaging element chip 110 are covered with the insulating film 150 such as a silicon dioxide film, for example, the regions of the scribed lines 109 at the time of dicing are laminates of the solid-state imaging element chip 110 and the insulating film 150.

However, the insulating film 150 such as a silicon dioxide film is a hard but non-viscous material. Therefore, there is a possibility that the product quality will be degraded due to chipping or cracking in the end surfaces at the time of dicing.

In the third embodiment, on the other hand, the regions of the scribed lines 109 are formed as laminates of the solid-state imaging element chip 110 and the silicon substrate 140. Silicon is a material that is soft and has good processability, and accordingly, chipping, cracking, and the like are less likely to occur at the time of dicing than in a case with silicon dioxide.

In view of this, in the third embodiment, such a configuration is adopted so that the occurrence of cracking and chipping at the time of dicing can be prevented.

Further, the silicon substrate 140 is bonded to the regions of the back surfaces of the electrode pads 113 to which the logic chip 120A and the memory chip 120B on the lower surface of the photodiode wiring layer 111 are not bonded. As the silicon substrate 140 is formed with silicon, which is substantially the same material as the solid-state imaging element chip 110, the linear expansion coefficient α as a whole is equalized.

Accordingly, the tensile stresses to be generated in the upper surface and the lower surface of the chip of the solid-state imaging device 100 can be equalized. Thus, the occurrence of warpage can be prevented.

### Configuration of a First Modification of the Third Embodiment

Next, the configuration of a first modification of the third embodiment is described. FIG. 36 is a schematic end view showing FIG. 35 regarding the basic form of the third embodiment in a further simplified manner. As illustrated in FIG. 36, in the basic form of the third embodiment, the outer shape of the silicon substrate 140 is formed in conformity with the outer shape of the solid-state imaging element chip 110, and the peripheral side surfaces of the silicon substrate 140 are formed in the same planes as the peripheral side surfaces of the solid-state imaging element chip 110.

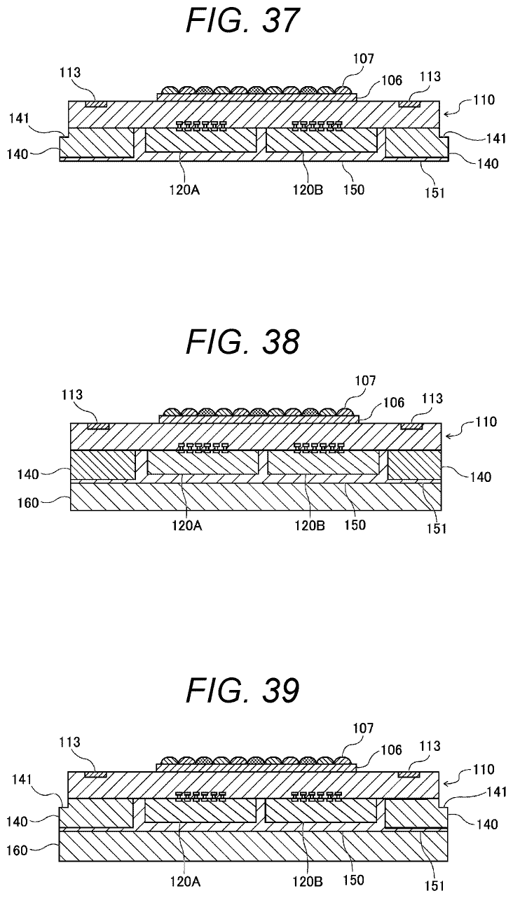

In the first modification, on the other hand, as illustrated in FIG. 37, steps 141 continuing from the peripheral side surfaces of the solid-state imaging element chip 110 bonded to the upper surface of the silicon substrate 140 to the peripheral side surfaces of the upper portion of the silicon substrate 140 are formed. That is, the upper peripheral side surfaces on the side of the solid-state imaging element chip 110 are formed to be smaller in width than the lower peripheral side surfaces on the side of the silicon substrate 140.

In this manner, the first modification differs from the basic form of the third embodiment in that the steps 141 are formed on the peripheral side surfaces on the side of the solid-state imaging element chip 110 bonded to the upper surface of the silicon substrate 140 and the peripheral side surfaces of the upper portion of the silicon substrate 140.

As such steps 141 are formed, singulation can be easily performed. Specifically, as described above, singulation is performed by cutting with a rotating blade called a blade 175. Therefore, as the steps 141 serving as cutting lines are formed along the scribed lines 109, it is only required to cut along the steps 141 between the adjacent solid-state imaging element chips 110 and 110, and the steps 141 serve as a cutting guide. Thus, the cutting can be performed accurately and easily. Other than the above, the configuration is similar to that of the basic form of the third embodiment, and therefore, explanation thereof is not made herein.

### Configuration of a Second Modification of the Third Embodiment

Next, the configuration of a second modification of the third embodiment is described. In the basic form of the third embodiment, any special-purpose substrate is not bonded to the lower surface of the insulating film 150, as illustrated in FIG. 36.

On the other hand, the second modification differs from the basic form in that the support substrate 160 is bonded to the lower surface of the insulating film 150 as illustrated in FIG. 38.

As such a support substrate 160 is bonded thereto, the solid-state imaging device 100 can be reinforced. Thus, strength can be secured, and the occurrence of warpage can be prevented. Other than the above, the configuration is similar to that of the basic form of the third embodiment, and therefore, explanation thereof is not made herein.

### Configuration of a Third Modification of the Third Embodiment

Next, the configuration of a third modification of the third embodiment is described. In the third modification, as illustrated in FIG. 39, the steps 141 continuing from the peripheral side surfaces of the solid-state imaging element chip 110 to the peripheral side surfaces of the upper portion of the silicon substrate 140 are formed, as in FIG. 37 illustrating the first modification. Further, the support substrate 160 is bonded to the lower surface of the insulating film 150, as in FIG. 38 illustrating the second modification. This modification differs from the basic form of the third embodiment in the above aspects.

Accordingly, singulation can be accurately and easily performed, and at the same time, the chip of the solid-state imaging device 100 is reinforced. Thus, strength can be secured, and the occurrence of warpage can be prevented. Other than the above, the configuration is similar to that of the basic form of the third embodiment, and therefore, explanation thereof is not made herein.

### Configuration of a Fourth Modification of the Third Embodiment

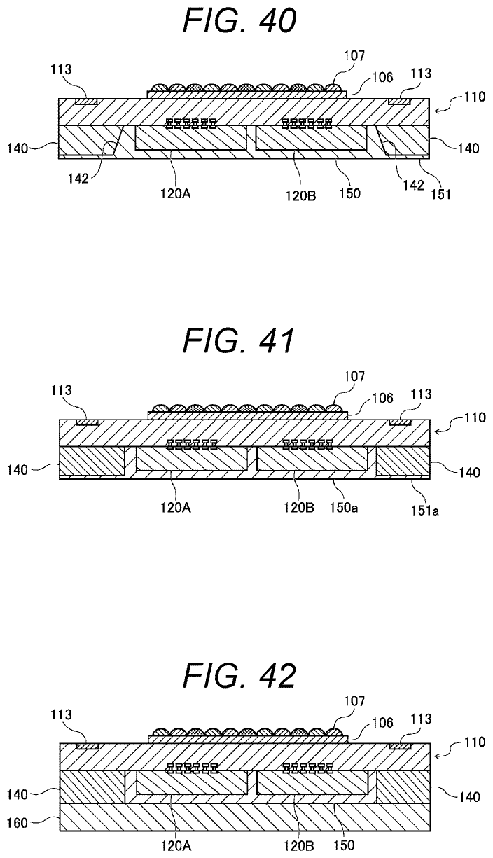

Next, the configuration of a fourth modification of the third embodiment is described. In the fourth modification, as illustrated in FIG. 40, the peripheral side surfaces of the insulating film 150 form tapered portions 142 that extend from the lower surface of the solid-state imaging element chip 110 and become wider at lower portions. That is, this modification differs from the basic form in that the peripheral side surfaces of the insulating film 150 have a tapered shape that is narrower at the upper side and is wider at the lower side. That is, in the fourth modification, the tapered portions 142 are formed on the peripheral side surfaces of the insulating film 150 of the basic form.

This facilitates formation of the silicon substrate 140 in the manufacturing process. Furthermore, when the insulating film 150 described later is replaced with an insulating resin 150a, it is easy to form the insulating resin 150a by adopting a structure having the tapered portions 142. Other than the above, the configuration is similar to that of the basic form of the third embodiment, and therefore, explanation thereof is not made herein.

### Configurations of Fifth to Seventh Modifications of the Third Embodiment

Next, the configurations of fifth to seventh modifications of the third embodiment are described. Note that drawings of the fifth to seventh modifications are not provided herein.

In the fifth modification, tapered portions 142 similar to those in FIG. 40 illustrating the fourth modification described above are formed on the peripheral side surfaces of the insulating film 150 in FIG. 37 illustrating the first modification.

In the sixth modification, tapered portions 142 similar to those in FIG. 40 illustrating the fourth modification described above are formed on the peripheral side surfaces of the insulating film 150 in FIG. 38 illustrating the second modification.

In the seventh modification, tapered portions 142 similar to those in FIG. 40 illustrating the fourth modification described above are formed on the peripheral side surfaces of the insulating film 150 in FIG. 39 illustrating the third modification.

The effects of each of these modifications are a combination of the effects unique to the fourth modification and the effects of each corresponding one of the first to third modifications. Other than the above, the configurations are similar to that of the basic form of the third embodiment, and therefore, explanation thereof is not made herein.

### Configurations of Eighth to Eleventh Modifications of the Third Embodiment

Next, the configurations of eighth to eleventh modifications of the third embodiment are described. Note that drawings of the ninth to eleventh modifications are not provided herein.

As illustrated in FIG. 41, the eighth modification differs from the basic form in that the peripheral side surfaces and the lower surfaces of the logic chip 120A and the memory chip 120B are covered with an insulating resin 150a such as a thermosetting epoxy resin or an organic resin, instead of the insulating film 150. That is, in the eighth modification, the insulating film 150 in FIG. 36 illustrating the basic form is replaced with the insulating resin 150a such as epoxy resin, for example. Likewise, instead of the insulating thin film 151, an insulating resin thin film 151a is formed on the lower surface of the processor chip 140.

The epoxy resin as the insulating resin 150a has many excellent characteristics such as high heat resistance, high adhesiveness, high fluidity, and low stress, and can be used in applications that utilize these features. Other than the above, the configuration is similar to that of the basic form of the third embodiment, and therefore, explanation thereof is not made herein.

In the ninth modification, the insulating film 150 in FIG. 37 illustrating the first modification is replaced with the insulating resin 150a such as epoxy resin, as in FIG. 41 illustrating the eighth modification described above.

In the tenth modification, the insulating film 150 in FIG. 38 illustrating the second modification is replaced with the insulating resin 150a such as epoxy resin, as in FIG. 41 illustrating the eighth modification described above.

In the eleventh modification, the insulating film 150 in FIG. 39 illustrating the third modification is replaced with the insulating resin 150a such as epoxy resin, as in FIG. 41 illustrating the eighth modification described above.

The effects of each of these modifications are a combination of the effects unique to the eighth modification and the effects of each corresponding one of the first to fourth modifications. Other than the above, the configurations are similar to that of the basic form of the third embodiment, and therefore, explanation thereof is not made herein.

### Configurations of Twelfth to Fifteenth Modifications of the Third Embodiment

Next, the configurations of twelfth to fifteenth modifications of the third embodiment are described. Note that drawings of the twelfth to fifteenth modifications are not provided herein.

In the twelfth modification, the portion of the insulating film 150 on the lower surface of the solid-state imaging element chip 110 forms the tapered portions 142 that become wider at lower portions, as in FIG. 40 illustrating the fourth modification. Further, the insulating film 150 is replaced with the insulating resin 150a such as epoxy resin, as in FIG. 41 illustrating the eighth modification described above.

That is, in the twelfth modification, tapered portions 142 similar to those in FIG. 40 illustrating the fourth modification are formed on the peripheral side surfaces of the insulating resin 150a in FIG. 41 illustrating the eighth modification.

This facilitates formation of the silicon substrate 140. Furthermore, the formation becomes easier in a structure that has the tapered portions 142 when the insulating film is formed with the insulating resin 150a. Other than the above, the configuration is similar to that of the basic form of the third embodiment, and therefore, explanation thereof is not made herein.

In the thirteenth modification, the tapered portions 142 similar to those in FIG. 40 illustrating the fourth modification are formed on the peripheral side surfaces of the insulating resin 150a of the ninth modification.

In the fourteenth modification, the tapered portions 142 similar to those in FIG. 40 illustrating the fourth modification are formed on the peripheral side surfaces of the insulating resin 150a of the tenth modification.

In the fifteenth modification, the tapered portions 142 similar to those in FIG. 40 illustrating the fourth modification are formed on the peripheral side surfaces of the insulating resin 150a of the eleventh modification.

The effects of each of these modifications are a combination of the effects unique to the tapered portions 142 in FIG. 40 illustrating the fourth modification and the effects of the insulating resin 150a of each corresponding one of the eighth to eleventh modifications. Other than the above, the configurations are similar to that of the basic form of the third embodiment, and therefore, explanation thereof is not made herein.

### Configurations of Sixteenth and Seventeenth Modifications of the Third Embodiment

Next, the configurations of sixteenth and seventeenth modifications of the third embodiment are described. In the sixteenth modification, as illustrated in FIG. 42, the lower surface of the silicon substrate 140 is not covered with the insulating thin film 151, and is bonded directly to the support substrate 160.

In the sixteenth modification, the lower surface of the silicon substrate 140 is bonded directly to the support substrate 160 in this manner, so that the solid-state imaging device 100 can be reinforced. Thus, strength can be secured, and the occurrence of warpage can be prevented. Furthermore, heat generated in the solid-state imaging element chip 110 can be transferred to the support substrate 160 via the silicon substrate 140 having a high thermal conductivity, and thus, the cooling effect can be enhanced. Other than the above, the configuration is similar to that of the basic form of the third embodiment, and therefore, explanation thereof is not made herein.

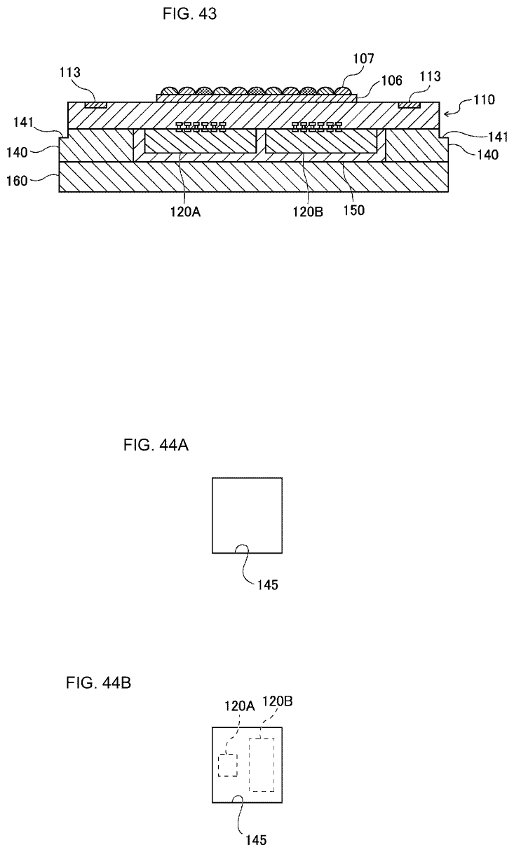

In the seventeenth modification, as illustrated in FIG. 43, the lower surface of the silicon substrate 140 is not covered with the insulating thin film 151, and is bonded directly to the support substrate 160. Further, the steps 141 are formed on the peripheral side surfaces of the solid-state imaging element chip 110. That is, in the seventeenth modification, the steps 141 continuing from the peripheral side surfaces of the solid-state imaging element chip 110 of the above-described sixteenth modification illustrated in FIG. 42 to the peripheral side surfaces of the upper portion of the silicon substrate 140 are formed.

Accordingly, the effects of the seventeenth modification is a combination of the effects of the third modification in FIG. 39 and the effects of the sixteenth modification in FIG. 42. Other than the above, the configurations are similar to that of the basic form of the third embodiment, and therefore, explanation thereof is not made herein.

### Configurations of Eighteenth and Nineteenth Modifications of the Third Embodiment

Next, the configurations of eighteenth and nineteenth modifications of the third embodiment are described. Note that drawings of the respective modifications are not provided herein.

In the eighteenth modification, tapered portions 142 similar to those in FIG. 40 illustrating the fourth modification are formed on the peripheral side surfaces of the insulating film 150 in FIG. 42 illustrating the sixteenth modification described above.

In the nineteenth modification, tapered portions 142 similar to those in FIG. 40 illustrating the fourth modification are formed on the peripheral side surfaces of the insulating film 150 in FIG. 43 illustrating the seventeenth modification described above.

The effects of each of these modifications are a combination of the effects unique to the tapered portions 142 in FIG. 40 illustrating the fourth modification and the effects of each corresponding one of the sixteenth and seventeenth modifications. Other than the above, the configurations are similar to that of the basic form of the third embodiment, and therefore, explanation thereof is not made herein.

### Configurations of Twentieth to Thirty-Ninth Modifications of the Third Embodiment

Next, the configurations of twentieth to thirty-ninth modifications of the third embodiment are described. Note that drawings of the respective modifications are not provided herein.

Each of these modifications differs from the basic form of the third embodiment and each of the first to nineteenth modifications in that the Cow connection between the photodiode wiring layer 111 of the solid-state imaging element chip 110 and the active chips 120 such as the logic chip 120A and the memory chip 120B is replaced with Cu—Cu connection.

The Cu—Cu connection eliminates the need to provide a TSV penetrating the chip, and makes the occupied region for connection unnecessary. Thus, a chip of the solid-state imaging device 100 can be made smaller in size, and productivity can be increased. Other than the above, the configurations are similar to that of the basic form of the third embodiment, and therefore, explanation thereof is not made herein.

### Configurations of Fortieth to Fifty-Ninth Modifications of the Third Embodiment

Next, the configurations of fortieth to fifty-ninth modifications of the third embodiment are described. Note that drawings of the respective modifications are not provided herein.

Each of these modifications differs from the basic form of the third embodiment and each of the first to nineteenth modifications in that the Cow connection between the photodiode wiring layer 111 of the solid-state imaging element chip 110 and the active chips 120 such as the logic chip 120A and the memory chip 120B is replaced with solder bump connection.

The solder bump connection eliminates the need to provide a through hole penetrating the chip, and makes the occupied region for connection unnecessary. Furthermore, as the wiring length can be shortened, high-speed signal processing can be performed. Thus, the solid-state imaging device 100 can be made smaller in size, and productivity can be increased. Other than the above, the configurations are similar to that of the basic form of the third embodiment, and therefore, explanation thereof is not made herein.

### Configurations of Sixtieth to Seventy-Ninth Modifications of the Third Embodiment

Next, the configurations of sixtieth to seventy-ninth modifications of the third embodiment are described. Note that drawings of the respective modifications are not provided herein.

Each of these modifications differs from the basic form of the third embodiment and each of the first to nineteenth modifications in that the Cow connection between the photodiode wiring layer 111 of the solid-state imaging element chip 110 and the active chips 120 such as the logic chip 120A and the memory chip 120B is replaced with gold bump connection.

The gold bump connection can further enhance connection reliability, in addition to having the advantages of the solder bump connection. Other than the above, the configurations are similar to that of the basic form of the third embodiment, and therefore, explanation thereof is not made herein.

### Configurations of Eightieth to Ninety-Ninth Modifications of the Third Embodiment

Next, the configurations of eightieth to ninety-ninth modifications of the third embodiment are described. Note that drawings of the respective modifications are not provided herein.

Each of these modifications differs from the basic form of the third embodiment and each of the first to nineteenth modifications in that the shape in a planar view of a dug portion 145 formed in a silicon substrate 140A or a hollow portion 146 formed in a silicon substrate 140B is one of the shapes illustrated in FIGS. 44 to 47. In the description below, example cases where the dug portion 145 is formed will be described with reference to FIGS. 44 to 47. Note that the same applies in a case with the hollow portion 146.

In FIG. 44A, the shape of the dug portion 145 in a planar view is a square shape. FIG. 44B is a diagram illustrating an example case where a total of two chips, which are a logic chip 120A and a memory chip 120B accommodated within the dug portion 145, are arranged.

In FIG. 45A, the shape of the dug portion 145 in a planar view is a square shape. FIG. 45B is a diagram illustrating an example case where a total of two chips, which are a logic chip 120A and a memory chip 120B accommodated within the dug portion 145, are arranged.

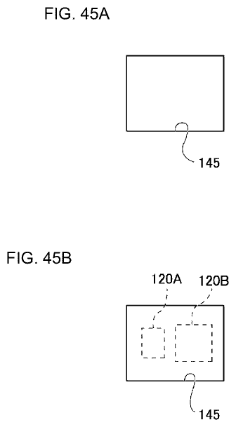

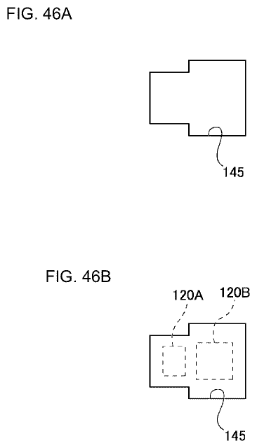

In FIG. 46A, the shape of the dug portion 145 in a planar view is a shape formed by joining two large and small rectangles. As illustrated in this drawing, a small rectangle protrudes from a side surface of a large rectangle. FIG. 46B is a diagram illustrating an example case where a total of two chips, which are a logic chip 120A and a memory chip 120B accommodated within the dug portion 145, are arranged.

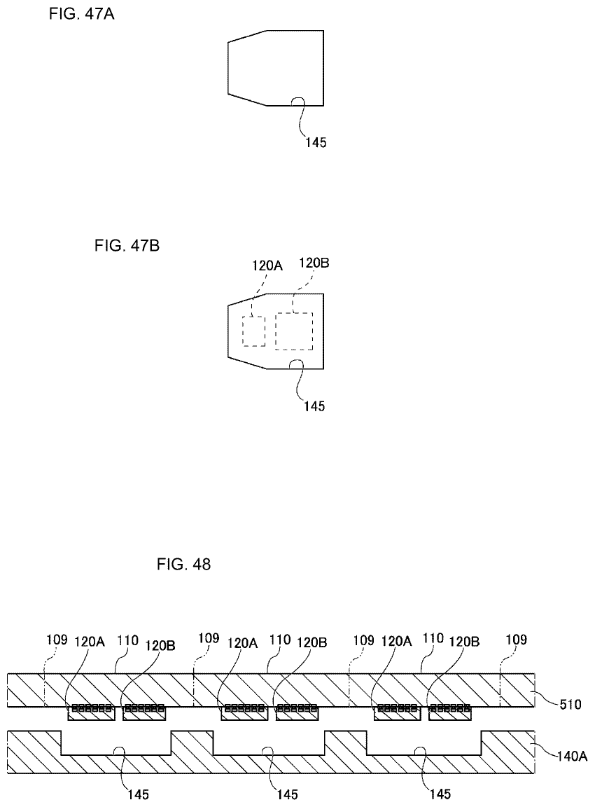

In FIG. 47A, the shape of the dug portion 145 in a planar view is a shape formed by joining the base of a trapezoid to a side of a rectangle. As illustrated in this drawing, the shape is a hexagonal shape in which a trapezoid protrudes from a side of a large rectangle. FIG. 47B is a diagram illustrating an example case where a total of two chips, which are a logic chip 120A and a memory chip 120B accommodated within the dug portion 145, are arranged.

The shape of the dug portion 145 in each planar view described above is an example, and an optimum shape can be selected in accordance with the size, the number, or the layout of the active chips 120, on the basis of the gist of the eightieth to ninety-ninth modifications.

### 6. Method for Manufacturing the Third Embodiment of a Solid-State Imaging Device According to the Present Disclosure

### Basic Form of a Method for Manufacturing the Third Embodiment

The process of manufacturing a Cow structure according to the basic form of a method for manufacturing the third embodiment of the solid-state imaging device 100 according to the present disclosure is similar to the contents described above in [Outline of a CoW Structure] of <1. First Embodiment of a Solid-State Imaging Device According to the Present Disclosure>, and therefore, explanation thereof is not made herein.

FIGS. 48 to 58 are diagrams illustrating a basic form of a process of coating solid-state imaging element chips 110 having logic chips 120A and memory chips 120B bonded thereto with an insulating film 150, forming a silicon substrate 140, and performing singulation by a method for manufacturing the third embodiment of the solid-state imaging device 100 according to the present disclosure.

As illustrated in FIG. 48, for example, logic chips 120A and memory chips 120B are bonded to the lower surfaces of solid-state imaging element chips 110 on a wafer 510. A silicon substrate 140A is then provided so as to face the lower surfaces of the solid-state imaging element chips 110. In the silicon substrate 140A, dug portions 145 having a shape that avoids contact with active chips 120 such as the logic chips 120A and the memory chips 120B are formed.

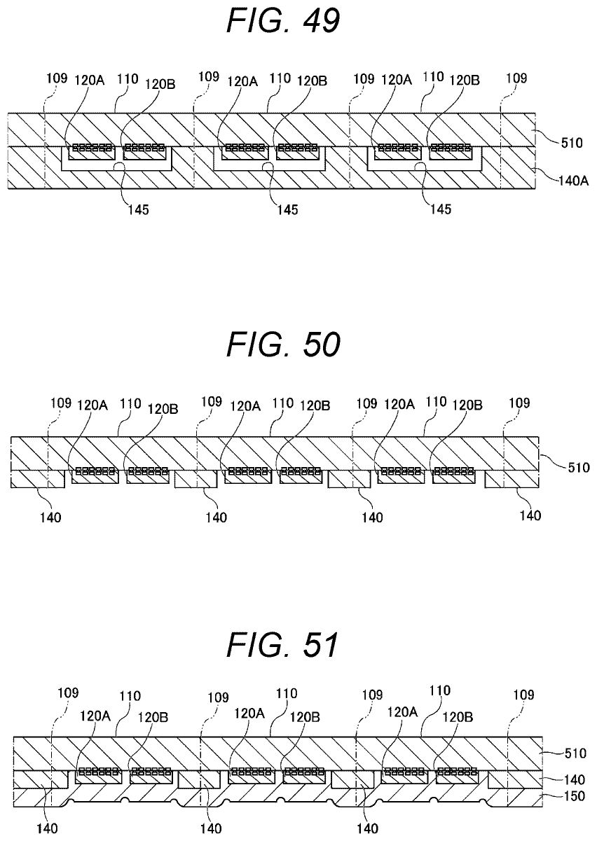

Next, as illustrated in FIG. 49, the silicon substrate 140A in which the dug portions 145 are formed is bonded to the lower surfaces of the solid-state imaging element chips 110 on the wafer 510.

Next, as illustrated in FIG. 50, the lower surface of the silicon substrate 140A bonded to the lower surfaces of the solid-state imaging element chips 110 is made thinner with a back grinder. As a result, the silicon substrate 140A remains between the dug portions 145 and 145, and a silicon substrate 140 is formed between each logic chip 120A and each memory chip 120B.

Next, as illustrated in FIG. 51, the logic chips 120A and the memory chips 120B are bonded, and an insulating film 150 is stacked on the lower surfaces of the solid-state imaging element chips 110 on which the silicon substrate 140 is formed. As a result, the logic chips 120A, the memory chips 120B, and the silicon substrate 140 are covered with the insulating film 150.

In this state, however, the insulating film 150 is stacked in conformity with the shapes of the irregularities of the logic chips 120A, the memory chips 120B, and the silicon substrate 140, and therefore, the surface thereof is in an uneven state.

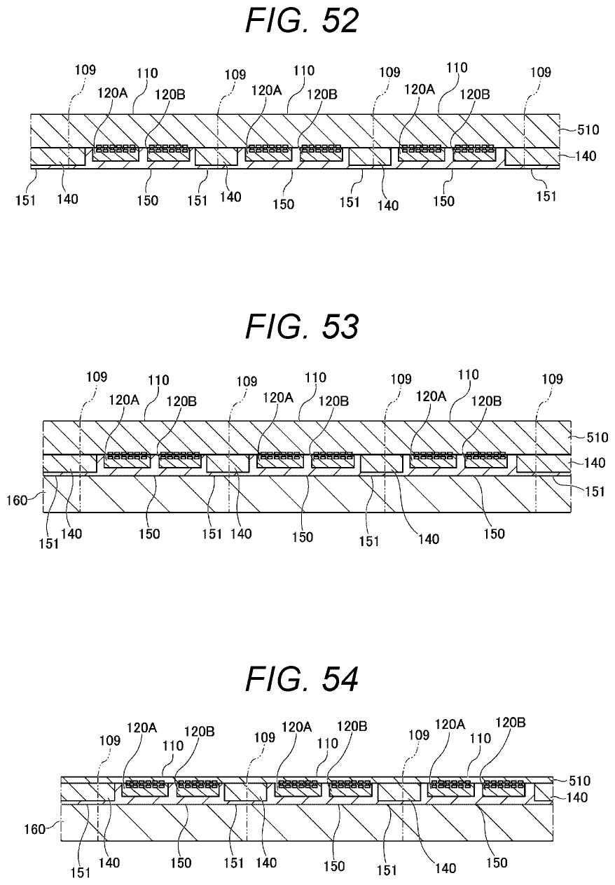

To counter this, as illustrated in FIG. 52, the lower surface of the stacked insulating film 150 is planarized and thinned by CMP.

In this CMP, the lower surface of the insulating film 150 is left thin so as to cover the entire lower surface of the silicon substrate 140, and an insulating thin film 151 is formed on the lower surface of the silicon substrate 140.

Next, as illustrated in FIG. 53, a support substrate 160 is bonded to the lower surfaces of the insulating film 150 and the insulating thin film 151.

Next, as illustrated in FIG. 54, the upper surfaces of the solid-state imaging element chips 110 are thinned by CMP or the like.

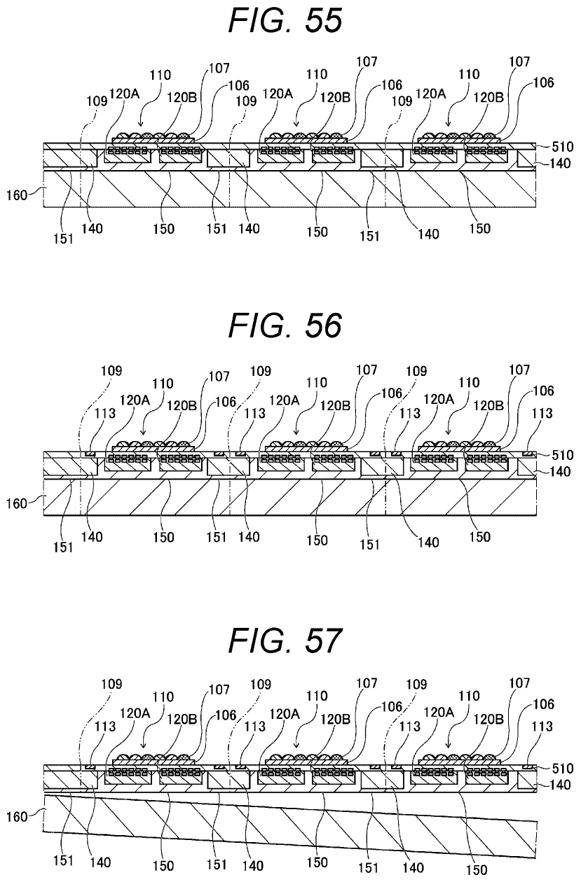

Next, as illustrated in FIG. 55, color filters 106, on-chip lenses 107, and the like are mounted on the upper surfaces of the thinned solid-state imaging element chips 110.

Next, as illustrated in FIG. 56, electrode pads 113 for wire bonding connection are formed at predetermined positions on the upper surfaces of the solid-state imaging element chips 110. The regions between the electrode pads 113 and the electrode pads 113 of the adjacent solid-state imaging element chips 110 serve as scribed lines 109 in singulation.

Next, as illustrated in FIG. 57, the support substrate 160 is removed from the lower surface of the insulating film 150.

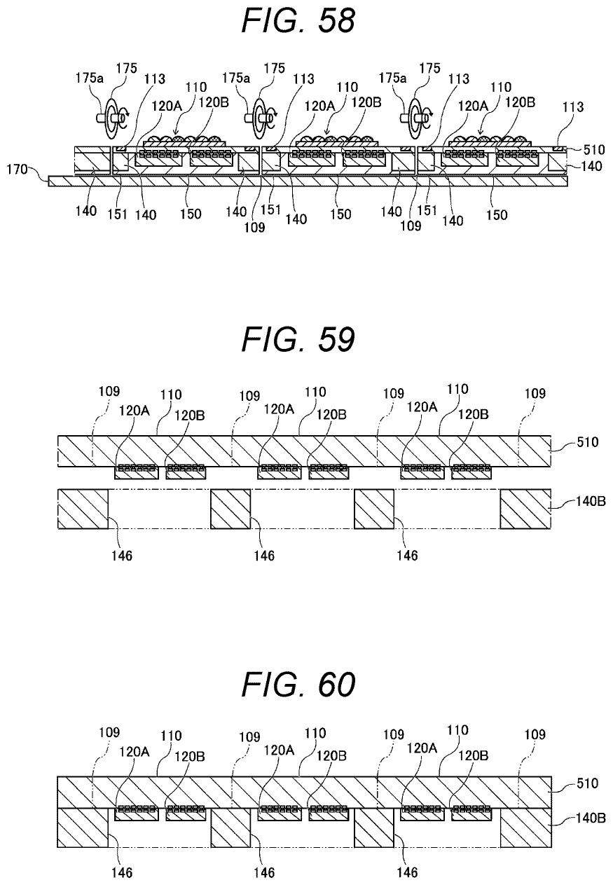

Next, as illustrated in FIG. 58, a protective dicing sheet 170 is attached to the lower surface of the insulating film 150. Dicing is then performed along the scribed lines 109 to perform singulation. The dicing is performed using a device called a dicer including a blade 175. The blade 175 is a disk-shaped grindstone, and is provided so as to be able to rotate about a predetermined rotation shaft 175a. That is, the depth position of the blade 175 with respect to the scribed lines 109 is adjusted, and the upper surface side of the solid-state imaging element chip 110 is linearly cut out for singulation at a predetermined depth by the rotating blade 175. Thus, singulation is performed.

As such a manufacturing process is included as described above, the solid-state imaging device 100 of the third embodiment according to the present disclosure can be manufactured through an inspection process or the like and a packaging process.

### First Modification of the Method for Manufacturing the Third Embodiment

FIGS. 59 to 61 are diagrams for explaining a first modification of the method for manufacturing the third embodiment of the solid-state imaging device 100 according to the present disclosure.

In the basic form of the method for manufacturing the third embodiment, the silicon substrate 140A having the dug portions 145 formed therein is bonded to the lower surfaces of the solid-state imaging element chips 110 on the wafer 510. In the first modification, on the other hand, the silicon substrate 140B having hollow portions 146 formed therein is bonded.

As illustrated in FIG. 59, for example, logic chips 120A and memory chips 120B are bonded to the lower surfaces of solid-state imaging element chips 110 on a wafer 510. A silicon substrate 140B is then provided so as to face the lower surfaces of the solid-state imaging element chips 110. In the silicon substrate 140B, hollow portions 146 having a shape that avoids contact with active chips 120 such as the logic chips 120A and the memory chips 120B are formed.

Next, as illustrated in FIG. 60, the silicon substrate 140B having the hollow portions 146 formed therein is bonded to the lower surfaces of the solid-state imaging element chips 110 on the wafer 510.

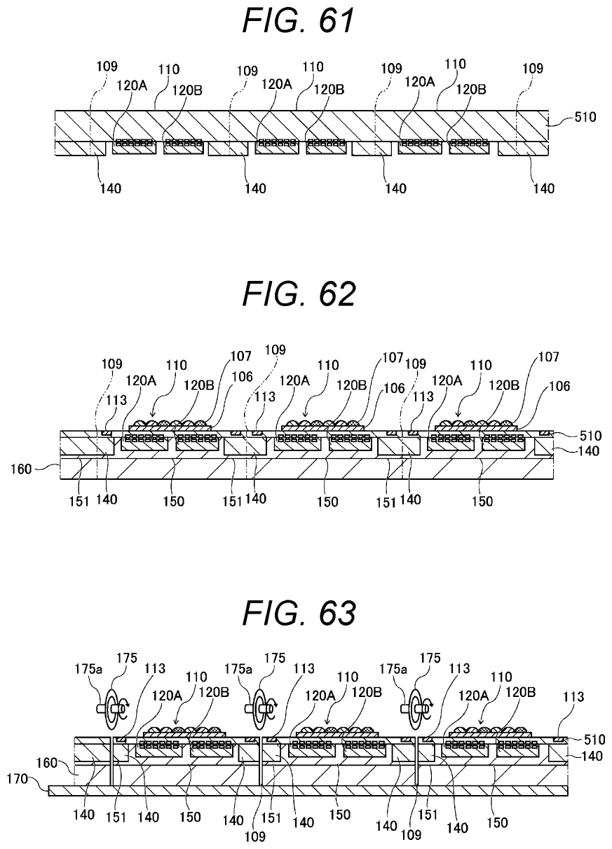

Next, as illustrated in FIG. 61, the lower surface of the silicon substrate 140B bonded to the lower surfaces of the solid-state imaging element chips 110 is made thinner with a back grinder. As a result, the silicon substrate 140B remains between the hollow portions 146 and 146, and a silicon substrate 140 is formed between each logic chip 120A and each memory chip 120B.

Subsequently, processes similar to those illustrated in FIGS. 51 to 58 relating to the basic form of the method for manufacturing the third embodiment described above are performed, so that singulation is performed. Thereafter, the solid-state imaging device 100 of the third embodiment according to the present disclosure can be manufactured through an inspection process or the like and a packaging process.

### Second Modification of the Method for Manufacturing the Third Embodiment

FIGS. 62 and 63 are diagrams for explaining a second modification of the method for manufacturing the third embodiment of the solid-state imaging device 100 according to the present disclosure.

In the basic form of the method for manufacturing the third embodiment, the thinned insulating film 150 is formed on the lower surface of the silicon substrate 140. In the second modification, on the other hand, a support substrate 160 is further provided on the lower surface of the thinned insulating film 150. Accordingly, in the second modification, FIGS. 48 to 56 in the basic form of the method for manufacturing the third embodiment are common, and therefore, explanation thereof is not made herein.

In the second modification of the method for manufacturing the third embodiment, explanation starts from the process illustrated in FIG. 56. As illustrated in FIG. 56, electrode pads 113 for wire bonding connection are formed at predetermined positions on the upper surfaces of the solid-state imaging element chips 110. The regions between the electrode pads 113 and the electrode pads 113 of the adjacent solid-state imaging element chips 110 serve as scribed lines 109.

Next, as illustrated in FIG. 62, the lower surface of the support substrate 160 is polished to be thinned.

Next, as illustrated in FIG. 63, a protective dicing sheet 170 is attached to the lower surface of the insulating film 150. Dicing is then performed along the scribed lines 109 to perform singulation. The dicing method is similar to that described with reference to FIG. 58 relating to the basic form of the method for manufacturing the third embodiment, and therefore, explanation thereof is not made herein.

As such a manufacturing process is included as described above, the solid-state imaging device 100 of the third embodiment according to the present disclosure can be manufactured through an inspection process or the like and a packaging process.

### Third Modification of the Method for Manufacturing the Third Embodiment

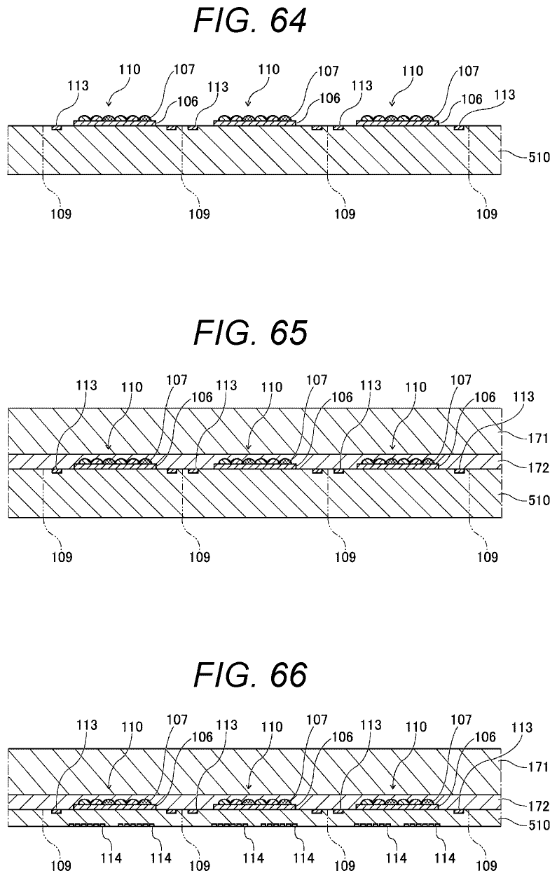

FIGS. 64 to 71 are diagrams for explaining a third modification of the method for manufacturing the third embodiment of the solid-state imaging device 100 according to the present disclosure.

In the basic form of the method for manufacturing the third embodiment, the thinned insulating film 150 remains on the lower surface of the silicon substrate 140. In the third modification of the method for manufacturing the third embodiment, on the other hand, a support substrate 160 is provided on the lower surface of the thinned insulating film 150.

Furthermore, in the basic form, after the silicon substrate 140 is bonded to the lower surfaces of the solid-state imaging element chips 110, on-chip lenses 107 and the like are formed. In the third modification, on the other hand, the silicon substrate 140 is bonded to the lower surfaces of the solid-state imaging element chips 110 after on-chip lenses 107 and the like are formed on the upper surfaces of the solid-state imaging element chips 110.

In the third modification of the method for manufacturing the third embodiment, color filters 106, on-chip lenses 107, and the like are first mounted on the upper surfaces of solid-state imaging element chips 110 on a wafer 510, as illustrated in FIG. 64.

Next, as illustrated in FIG. 65, an adhesive layer 172 is formed on the upper surfaces of the solid-state imaging element chips 110 including the on-chip lenses 107, and a temporary substrate 171 is attached onto the upper surface thereof.

Next, as illustrated in FIG. 66, the lower surfaces of the solid-state imaging element chips 110 are polished to be thinned. Terminals 114 for connection to the logic chips 120A and the memory chips 120B are then formed on the polished surfaces.

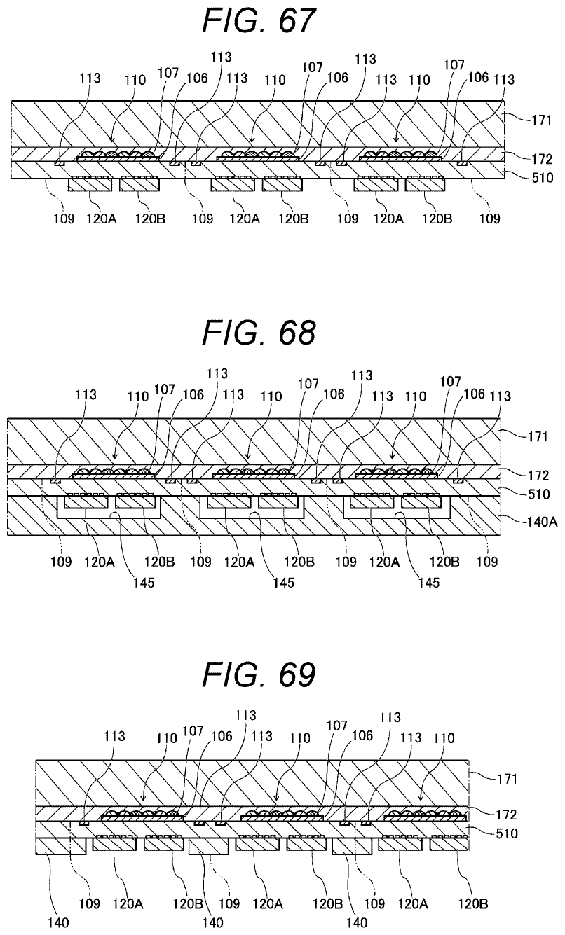

Next, as illustrated in FIG. 67, the logic chips 120A and the memory chips 120B are Cu—Cu connected to the lower surfaces of the solid-state imaging element chips 110. As described above with reference to FIG. 35, Cu—Cu connection is performed by bonding the terminals 114 of the solid-state imaging element chips 110 to the terminals 124 of the logic chips 120A and the memory chips 120B. As a result, the logic chips 120A and the memory chips 120B are physically and electrically connected to the solid-state imaging element chips 110.

Next, as illustrated in FIG. 68, the lower surface of the wafer 510 to which the logic chips 120A and the memory chips 120B are bonded is bonded to a silicon substrate 140A in which dug portions 145 having a shape that avoids contact with the active chips 120 are formed as illustrated in FIG. 49. Alternatively, as illustrated in FIG. 60, a silicon substrate 140B in which hollow portions 146 having a shape that avoids contact with the active chips 120 are bored may be bonded.

Next, as illustrated in FIG. 69, the lower surface of the silicon substrate 140A bonded to the lower surface of the wafer 510 is made thinner with a back grinder. As a result, the silicon substrate 140A remains between the dug portions 145 and 145, and a silicon substrate 140 is formed between each logic chip 120A and each memory chip 120B. Alternatively, as illustrated in FIG. 60 described above, in a case where the silicon substrate 140B in which the hollow portions 146 are formed is bonded, the lower surface of the silicon substrate 140B is thinned with a back grinder, to form the silicon substrate 140.

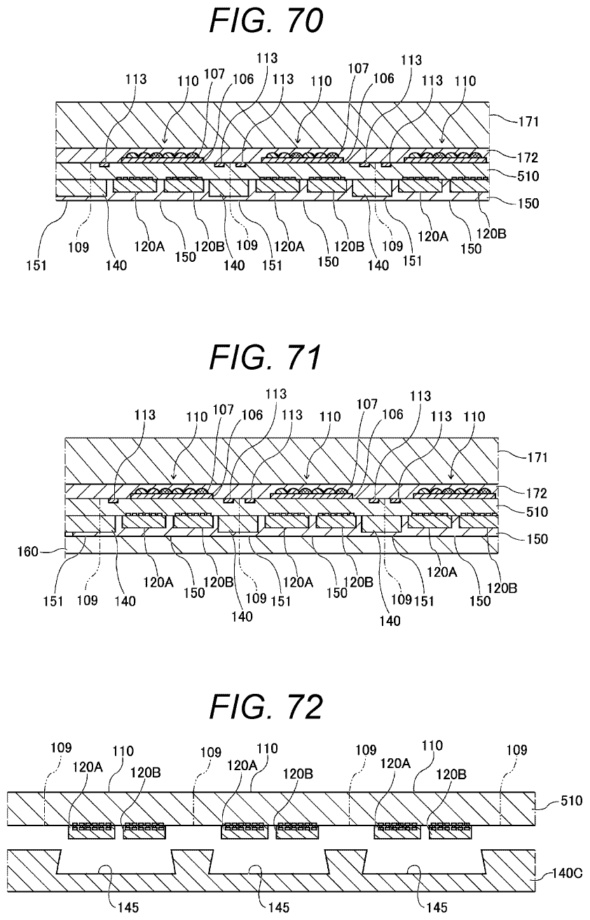

Next, as illustrated in FIG. 70, the logic chips 120A and the memory chips 120B are bonded, and an insulating film 150 is stacked on the lower surfaces of the solid-state imaging element chips 110 on which the silicon substrate 140 is formed. The lower surface of the stacked insulating film 150 is then planarized to be thinned by CMP in a manner similar to that described with reference to FIGS. 51 and 52 described above. In this CMP, the lower surface of the insulating film 150 is left thin so as to cover the entire lower surface of the silicon substrate 140, and an insulating thin film 151 is formed on the lower surface of the silicon substrate 140.

Next, as illustrated in FIG. 71, a support substrate 160 is bonded to the lower surfaces of the insulating film 150 including the insulating thin film 151.

Next, the temporary substrate 171 on the upper surfaces of the solid-state imaging element chips 110 including the on-chip lenses 107 is separated, and the adhesive layer 172 is removed by cleaning. As a result, the state illustrated in FIG. 62 in the second modification of the method for manufacturing the third embodiment can be obtained.

Next, as illustrated in FIG. 63 in the second modification described above, a protective dicing sheet 170 is attached to the lower surface of the insulating film 150. Dicing is then performed along the scribed lines 109 to perform singulation. The dicing method is similar to that described with reference to FIG. 58 relating to the basic form of the method for manufacturing the third embodiment, and therefore, explanation thereof is not made herein.

As such a manufacturing process is included as described above, the solid-state imaging device 100 of the third embodiment according to the present disclosure can be manufactured through an inspection process or the like and a packaging process.

### Fourth Modification of the Method for Manufacturing the Third Embodiment

FIGS. 72 to 75 are diagrams for explaining a fourth modification of the method for manufacturing the third embodiment of the solid-state imaging device 100 according to the present disclosure.

In the basic form of the method for manufacturing the third embodiment, the peripheral side surfaces of the dug portions 145 formed in the silicon substrate 140A are perpendicular to the lower surface of the silicon substrate 140A. In the fourth modification, on the other hand, the inner peripheral surfaces of the dug portions 145 are formed in a tapered shape that is wider at a lower portion.

In the fourth modification of the method for manufacturing the third embodiment, as illustrated in FIG. 72, for example, logic chips 120A and memory chips 120B are bonded to the lower surfaces of solid-state imaging element chips 110 on a wafer 510. A silicon substrate 140C is then provided so as to face the lower surfaces of the solid-state imaging element chips 110. In the silicon substrate 140A, dug portions 145 with tapered inner peripheral surfaces having a shape that avoids contact with active chips 120 such as the logic chips 120A and the memory chips 120B are formed.

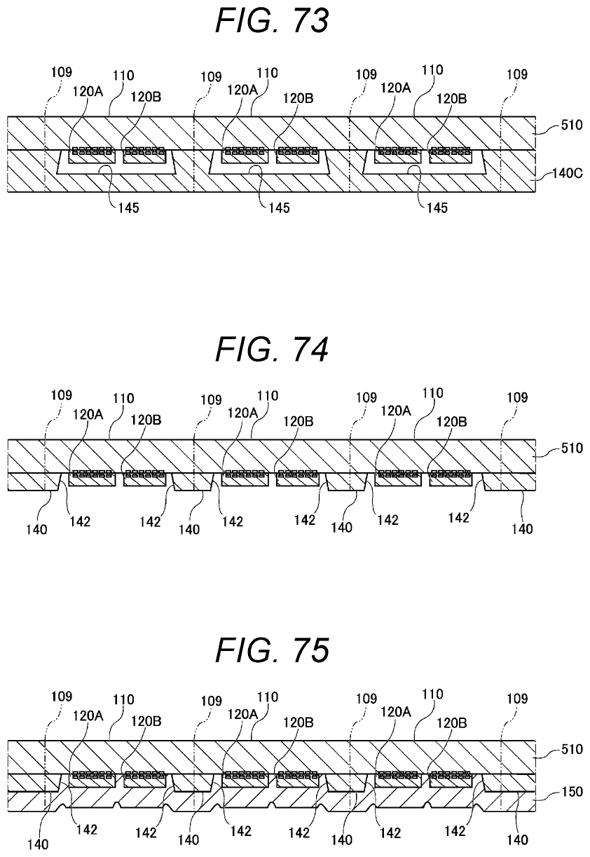

Next, as illustrated in FIG. 73, the silicon substrate 140C having the tapered dug portions 145 is bonded to the lower surfaces of the solid-state imaging element chips 110 on the wafer 510.

Next, as illustrated in FIG. 74, the lower surface of the silicon substrate 140C is thinned with a back grinder. As a result, the silicon substrate 140A remains between the tapered dug portions 145 and 145, and a silicon substrate 140 having tapered portions 142 is formed between each logic chip 120A and each memory chip 120B.

Next, as illustrated in FIG. 75, the logic chips 120A and the memory chips 120B are bonded, and an insulating film 150 is stacked on the lower surfaces of the solid-state imaging element chips 110 on which the silicon substrate 140 is formed. As a result, the logic chips 120A, the memory chips 120B, and the silicon substrate 140 are covered with the insulating film 150 in a manner similar to that illustrated in FIG. 51.

Subsequently, processes similar to those illustrated in FIGS. 52 to 58 relating to the basic form of the method for manufacturing the third embodiment described above are performed, so that singulation is performed. Thereafter, the solid-state imaging device 100 according to the fourth modification of the third embodiment can be manufactured through an inspection process or the like and a packaging process.

### 7. Example Configuration of an Electronic Apparatus

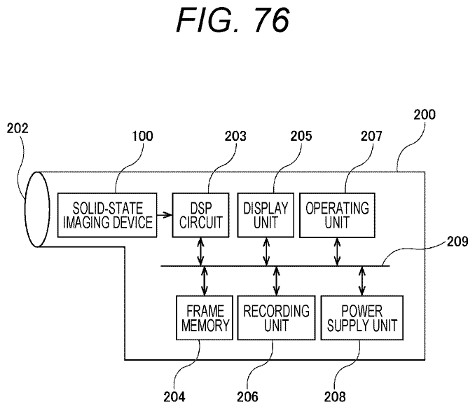

An example of an application of the solid-state imaging device 100 according to each of the embodiments described above to an electronic apparatus is now described with reference to FIG. 76. Note that this example application is common to the solid-state imaging devices 100 according to the first to third embodiments.

The solid-state imaging device 100 can be applied to all electronic apparatuses using an image capturing unit (photoelectric conversion unit), such as an imaging apparatus 200 such as a digital still camera or a video camera, a mobile terminal apparatus having an imaging function, and a copying machine using the solid-state imaging device 100 for an image reading unit. The solid-state imaging device 100 may be formed as one chip, or may be a packaged solid-state imaging device 100. Alternatively, the solid-state imaging device 100 may be in the form of a module having an imaging function in which an imaging unit and a signal processing unit or an optical system are packaged together.

As illustrated in FIG. 76, an imaging apparatus 200 as an electronic apparatus includes an optical unit 202, the solid-state imaging device 100, a digital signal processor (DSP) circuit 203 that is a camera signal processing circuit, a frame memory 204, a display unit 205, a recording unit 206, an operating unit 207, and a power supply unit 208. The DSP circuit 203, the frame memory 204, the display unit 205, the recording unit 206, the operating unit 207, and the power supply unit 208 are connected to each other via a bus line 209 including a signal line and a power supply line.

The optical unit 202 includes a plurality of lenses, and captures incident light (image light) from the subject to form an image on the imaging surface of the solid-state imaging device 100. The solid-state imaging device 100 converts the amount of the incident light imaged on the imaging surface by the optical unit 202 into an electrical signal in units of pixels, and outputs the electrical signal as a pixel signal.

The display unit 205 includes a panel-type display device such as a liquid crystal panel or an organic electro luminescence (EL) panel, for example, and displays a moving image or a still image captured by the solid-state imaging device 100. The recording unit 206 records the moving image or the still image captured by the solid-state imaging device 100 on a recording medium such as a hard disk or a semiconductor memory.

The operating unit 207 issues operation commands for various functions of the imaging apparatus 200, in accordance with an operation by a user. The power supply unit 208 supplies various power sources serving as operating power sources of the DSP circuit 203, the frame memory 204, the display unit 205, the recording unit 206, and the operating unit 207, to these supply targets.

With the imaging apparatus 200 described above, it is possible to realize downsizing and weight reduction so that the solid-state imaging device 100 having a reduced thickness and size can be used. Furthermore, the degree of integration can be increased, and thus, a captured image with high image quality can be obtained.

Lastly, the description of each of the embodiments described above is an example of the present disclosure, and the present disclosure is not limited to the embodiments described above. For this reason, it is needless to say that various modifications other than each of the above embodiments can be made in accordance with the design and the like, without departing from the technical idea according to the present disclosure. Furthermore, the effects described in the present specification are merely examples and are not restrictive, and other effects may be further achieved.

Note that the present technology may also have the configurations described below.
(1)
A solid-state imaging device including:
   a solid-state imaging element chip;
   at least one active chip that is bonded to a lower surface of the solid-state imaging element chip;
   a dummy chip that is bonded to a lower surface of an electrode pad of the solid-state imaging element chip, and has an end surface parallel to a cutting plane of the solid-state imaging element chip cut out from a wafer; and
   a planarized insulating film that covers a bonding surface of the solid-state imaging element chip including the active chip and the dummy chip.
(2)
The solid-state imaging device according to (1), in which the active chip is a logic chip, a memory chip, or a processor chip.
(3)
The solid-state imaging device according to (1) or (2), in which the electrode pad is disposed at both ends or peripheral ends of an upper surface of the solid-state imaging element chip, and the dummy chip is bonded in such a manner as to have an end surface in the same plane as a cutting plane of the solid-state imaging element chip.
(4)
The solid-state imaging device according to (1) or (2), in which the electrode pad is disposed at both ends or peripheral ends of an upper surface of the solid-state imaging element chip, and the active chip or the dummy chip is bonded in such a manner as to have a planar end surface adjacent to a cutting plane of the solid-state imaging element chip.
(5)
The solid-state imaging device according to any one of (1) to (4), in which the solid-state imaging element chip is Cu—Cu connected to the active chip or the dummy chip.
(6)
The solid-state imaging device according to any one of (1) to (4), in which the solid-state imaging element chip is Cu—Cu connected to the active chip, and is bonded to the dummy chip with an insulating film.
(7)
The solid-state imaging device according to any one of (1) to (4), in which the solid-state imaging element chip has a laminated structure including a photodiode formation layer and a photodiode wiring layer in which the electrode pad is disposed, and is Cu—Cu connected to the active chip or the dummy chip.
(8)
The solid-state imaging device according to any one of (1) to (4), in which the solid-state imaging element chip has a laminated structure including a photodiode formation layer and a photodiode wiring layer in which the electrode pad is disposed, is Cu—Cu connected to the active chip, and is bonded to the dummy chip with an insulating film.
(9)
A solid-state imaging device including:
   a solid-state imaging element chip;
   at least one active chip that is bonded to the solid-state imaging element chip;
   at least one dummy chip that is bonded to a free region on a bonding surface of the active chip of the solid-state imaging element chip, the active chip not being bonded to the free region; and
   a planarized insulating film that covers the bonding surface side of the solid-state imaging element chip including the active chip and the dummy chip.
(10)
The solid-state imaging device according to (9), in which a plurality of rectangular or strip-shaped dummy chips smaller than the active chip is bonded to the free region to which the active chip is not bonded.
(11)
The solid-state imaging device according to (9) or (10), in which the dummy chip is formed in a square or strip-like shape having a minimum short side of the free region as one side at a distance of at least 0.5 μm from an end surface of the active chip bonded to the solid-state imaging element chip, and the dummy chip is bonded to the free region, with the distance being secured.
(12)
The solid-state imaging device according to any one of (9) to (11), in which the dummy chip contains at least one of silicon (Si), aluminum oxide (Al₂O₃), silicon carbide (Sic), aluminum nitride (AlN), silicon nitride (Si₃N₄), titanium (Ti), titanium nitride (TiN), carbon (C), silicon carbonitride (SiCN), polysilicon, or tantalum nitride (TaN).
(13)
The solid-state imaging device according to any one of (9) to (11), in which, in the dummy chip or the active chip, at least one of silicon (Si), aluminum oxide (Al₂O₃), silicon carbide (Sic), aluminum nitride (AlN), silicon nitride (Si₃N₄), titanium (Ti), titanium nitride (TiN), aluminum (Al), carbon (C), silicon carbonitride (SiCN), polysilicon, or tantalum nitride (TaN), which is a material having a polishing rate of 20 or higher with respect to silicon dioxide (SiO₂), is stacked on a surface on the opposite side from a surface of bonding to the solid-state imaging element chip.
(14)
The solid-state imaging device according to any one of (9) to (11), in which the dummy chip includes a heat transfer member that is formed with a material having a higher thermal conductivity than a thermal conductivity of silicon dioxide (SiO₂), and is stacked on a single layer or multiple layers.
(15)
A solid-state imaging device including:
   a solid-state imaging element chip;
   at least one active chip that is bonded to the solid-state imaging element chip;
   a silicon substrate that is bonded to the solid-state imaging element chip to surround a peripheral side surface of the active chip; and
   a planarized insulating film that covers a region between the active chip and the silicon substrate, and at least a lower surface of the active chip.
(16)
The solid-state imaging device according to (15), in which a peripheral side surface of the silicon substrate is formed in the same plane as a peripheral side surface of the solid-state imaging element chip.
(17)
The solid-state imaging device according to (15), in which a step continuing from a peripheral side surface of the solid-state imaging element chip to a peripheral side surface of an upper portion of the silicon substrate is formed.
(18)
The solid-state imaging device according to any one of (15) to (17), in which a support substrate is bonded to a lower surface of the silicon substrate or the insulating film.
(19)
The solid-state imaging device according to any one of (15) to (18), in which a peripheral side surface of the insulating film in contact with the silicon substrate has a tapered portion that extends from a bonding surface of the solid-state imaging element chip and is wider at a lower portion.
(20)
The solid-state imaging device according to any one of (15) to (19), in which the insulating film includes an insulating resin.
(21)
A method for manufacturing a solid-state imaging device, the method including:
   a step of bonding an active chip to a lower surface of a solid-state imaging element chip on a wafer;
   a step of bonding a silicon substrate to the lower surface of the solid-state imaging element chip, a dug portion or a hollow portion being formed in the silicon substrate, the dug portion or the hollow portion having a shape that avoids contact with the active chip;
   a step of thinning a lower surface of the silicon substrate to leave part of the silicon substrate between the active chips;
   a step of stacking an insulating film on the lower surface of the solid-state imaging element chip to cover a region between the active chip and the remaining silicon substrate; and
   a step of planarizing the covering insulating film.
(22)
An electronic apparatus including
   a solid-state imaging device including:
   a solid-state imaging element chip;
   at least one active chip that is bonded to a lower surface of the solid-state imaging element chip;
   a dummy chip that is bonded to a lower surface of an electrode pad of the solid-state imaging element chip, and has an end surface parallel to a cutting plane of the solid-state imaging element chip cut out from a wafer; and
   a planarized insulating film that covers the bonding surface of the solid-state imaging element chip including the active chip and the dummy chip,
   a solid-state imaging device including:
   a solid-state imaging element chip;
   at least one active chip that is bonded to the solid-state imaging element chip;
   at least one dummy chip that is bonded to a free region on a bonding surface of the active chip of the solid-state imaging element chip, the active chip not being bonded to the free region; and
   a planarized insulating film that covers the bonding surface side of the solid-state imaging element chip including the active chip and the dummy chip, or
   a solid-state imaging device including:
   a solid-state imaging element chip;
   at least one active chip that is bonded to the solid-state imaging element chip;
   a silicon substrate that is bonded to the solid-state imaging element chip to surround a peripheral side surface of the active chip; and
   a planarized insulating film that covers a region between the active chip and the silicon substrate, and at least a lower surface of the active chip.

### REFERENCE SIGNS LIST

100 Solid-state imaging device
101 Photoelectric conversion unit
102 Photodiode formation layer
103 Pixel region
106 Color filter
107 On-chip lens
109 Scribed line
110 Solid-state imaging element chip
110n Defective chip
111 Photodiode wiring layer
112 Wiring line
113 Electrode pad
114 Terminal
115 Via
120 Active chip
120A Logic chip
120B Memory chip
121 Wiring layer
122 Wiring line
124 Terminal
125 Via
130 Dummy chip
130L Dummy chip
130s Dummy chip
130P Dummy chip
130p Dummy film
130H Dummy chip
130h Dummy film
130a, b, c Dummy chip
130t End surface
131 Processor chip
140 Silicon substrate
140A Silicon substrate
140B Silicon substrate
141 Step
142 Tapered portion
145 Dug portion
146 Hollow portion
150 Insulating film
150a Insulating resin
151 Insulating thin film
151a Insulating resin thin film
160 Support substrate
170 Dicing sheet
171 Temporary substrate
172 Adhesive layer
175 Blade 175a Rotation shaft
200 Imaging apparatus
510 Wafer
520 Wafer
521 Wafer
530 Wafer
531 Wafer

1. A solid-state imaging device comprising:
a solid-state imaging element chip;
at least one active chip that is bonded to a lower surface of the solid-state imaging element chip;
a dummy chip that is bonded to a lower surface of an electrode pad of the solid-state imaging element chip, and has an end surface parallel to a cutting plane of the solid-state imaging element chip cut out from a wafer; and
a planarized insulating film that covers the bonding surface of the solid-state imaging element chip including the active chip and the dummy chip.

2. The solid-state imaging device according to claim 1, wherein the active chip includes one of a logic chip, a memory chip, or a processor chip.

3. The solid-state imaging device according to claim 1, wherein the electrode pad is disposed at both ends or a peripheral end of an upper surface of the solid-state imaging element chip, and the dummy chip is bonded to have an end surface in the same plane as a cutting plane of the solid-state imaging element chip.

4. The solid-state imaging device according to claim 1, wherein the electrode pad is disposed at both ends or a peripheral end of an upper surface of the solid-state imaging element chip, and one of the active chip or the dummy chip is bonded to have a planar end surface adjacent to a cutting plane of the solid-state imaging element chip.

5. The solid-state imaging device according to claim 1, wherein the solid-state imaging element chip is Cu—Cu connected to one of the active chip or the dummy chip.

6. The solid-state imaging device according to claim 1, wherein the solid-state imaging element chip is Cu—Cu connected to the active chip, and is bonded to the dummy chip with an insulating film.

7. The solid-state imaging device according to claim 1, wherein the solid-state imaging element chip has a laminated structure including a photodiode formation layer and a photodiode wiring layer in which the electrode pad is disposed, and is Cu—Cu connected to one of the active chip or the dummy chip.

8. The solid-state imaging device according to claim 1, wherein the solid-state imaging element chip has a laminated structure including a photodiode formation layer and a photodiode wiring layer in which the electrode pad is disposed, is Cu—Cu connected to the active chip, and is bonded to the dummy chip with an insulating film.

9. A solid-state imaging device comprising:
a solid-state imaging element chip;
at least one active chip that is bonded to the solid-state imaging element chip;
at least one dummy chip that is bonded to a free region on a bonding surface of the active chip of the solid-state imaging element chip, the active chip not being bonded to the free region; and
a planarized insulating film that covers the bonding surface side of the solid-state imaging element chip including the active chip and the dummy chip.

10. The solid-state imaging device according to claim 9, wherein a plurality of rectangular or strip-shaped dummy chips smaller than the active chip is bonded to the free region to which the active chip is not bonded.

11. The solid-state imaging device according to claim 9, wherein the dummy chip is formed in a substantially square or strip-like shape having a minimum short side of the free region as one side at a distance of at least 0.5 μm from an end surface of the active chip bonded to the solid-state imaging element chip, and the dummy chip is bonded to the free region, with the distance being secured.

12. The solid-state imaging device according to claim 9, wherein the dummy chip contains at least one of silicon (Si), aluminum oxide (Al₂O₃), silicon carbide (Sic), aluminum nitride (AlN), silicon nitride (Si₃N₄), titanium (Ti), titanium nitride (TiN), carbon (C), silicon carbonitride (SiCN), polysilicon, or tantalum nitride (TaN).

13. The solid-state imaging device according to claim 9, wherein, in one of the dummy chip or the active chip, at least one of silicon (Si), aluminum oxide (Al₂O₃), silicon carbide (SiC), aluminum nitride (AlN), silicon nitride (Si₃N₄), titanium (Ti), titanium nitride (TiN), aluminum (Al), carbon (C), silicon carbonitride (SiCN), polysilicon, or tantalum nitride (TaN), which is a material having a polishing rate of at least 20 with respect to silicon dioxide (SiO₂), is stacked on a surface on an opposite side from a surface of bonding to the solid-state imaging element chip.

14. The solid-state imaging device according to claim 9, wherein the dummy chip includes a heat transfer member that is formed with a material having a higher thermal conductivity than a thermal conductivity of silicon dioxide (SiO₂), and is stacked on a single layer or multiple layers.

15. A solid-state imaging device comprising:
a solid-state imaging element chip;
at least one active chip that is bonded to the solid-state imaging element chip;
a silicon substrate that is bonded to the solid-state imaging element chip to surround a peripheral side surface of the active chip; and
a planarized insulating film that covers a region between the active chip and the silicon substrate, and at least a lower surface of the active chip.

16. The solid-state imaging device according to claim 15, wherein a peripheral side surface of the silicon substrate is formed in the same plane as a peripheral side surface of the solid-state imaging element chip.

17. The solid-state imaging device according to claim 15, wherein a step continuing from a peripheral side surface of the solid-state imaging element chip to a peripheral side surface of an upper portion of the silicon substrate is formed.

18. The solid-state imaging device according to claim 15, wherein a support substrate is bonded to a lower surface of one of the silicon substrate or the insulating film.

19. The solid-state imaging device according to claim 15, wherein a peripheral side surface of the insulating film in contact with the silicon substrate has a tapered portion that extends from a bonding surface of the solid-state imaging element chip and is wider at a lower portion.

20. The solid-state imaging device according to claim 15, wherein the insulating film includes an insulating resin.

21. A method for manufacturing a solid-state imaging device,
the method comprising:
a step of bonding an active chip to a lower surface of a solid-state imaging element chip on a wafer;
a step of bonding a silicon substrate to the lower surface of the solid-state imaging element chip, one of a dug portion or a hollow portion being formed in the silicon substrate, the one of the dug portion or the hollow portion having a shape that avoids contact with the active chip;
a step of thinning a lower surface of the silicon substrate to leave part of the silicon substrate between the active chips;
a step of stacking an insulating film on the lower surface of the solid-state imaging element chip to cover a region between the active chip and the remaining silicon substrate; and
a step of planarizing the covering insulating film.

22. An electronic apparatus comprising one of a solid-state imaging device including:
a solid-state imaging element chip;
at least one active chip that is bonded to a lower surface of the solid-state imaging element chip;
a dummy chip that is bonded to a lower surface of an electrode pad of the solid-state imaging element chip, and has an end surface parallel to a cutting plane of the solid-state imaging element chip cut out from a wafer; and
a planarized insulating film that covers the bonding surface of the solid-state imaging element chip including the active chip and the dummy chip,
a solid-state imaging device including:
a solid-state imaging element chip;
at least one active chip that is bonded to the solid-state imaging element chip;
at least one dummy chip that is bonded to a free region on a bonding surface of the active chip of the solid-state imaging element chip, the active chip not being bonded to the free region; and
a planarized insulating film that covers the bonding surface side of the solid-state imaging element chip including the active chip and the dummy chip, or
a solid-state imaging device including:
a solid-state imaging element chip;
at least one active chip that is bonded to the solid-state imaging element chip;
a silicon substrate that is bonded to the solid-state imaging element chip to surround a peripheral side surface of the active chip; and
a planarized insulating film that covers a region between the active chip and the silicon substrate, and at least a lower surface of the active chip.
